(19) United States
(12) Patent Application Publication
(10) Pub. No.: US 2026/0333565 A1
(43) Pub. Date: Oct. 22, 2026

(54) SPLIT HEAT SINK COOLING SYSTEM FOR ENHANCED SERVICEABILITY

(71) Applicant: NVIDIA Corporation, Santa Clara, CA (US)

(72) Inventor: Jay Gite, San Jose, CA (US)

(21) Appl. No.: 19/314,081

(22) Filed: Aug. 29, 2025

Related U.S. Application Data
(60) Provisional application No. 63/790,302, filed on Apr. 17, 2025.

(51) Int. Cl. H05K 1/02

(52) U.S. Cl. CPC H05K 1/0203; H05K 2201/064

(57) ABSTRACT

A heat sink comprises a first section to extract heat generated by a high-power component, and at least a second section, attachable to and detachable from the first section, to extract heat generated by a low-power component. The at least a second section, when attached to the first section, is thermally coupled to the first section such that the heat generated by the high-power component is further dissipated by the at least a second section.

### CROSS-REFERENCE TO RELATED APPLICATION

The present application claims the benefit of and priority under 35 U.S.C. § 119 to U.S. Provisional Application Ser. No. 63/790,302, filed Apr. 17, 2025, entitled “SPLIT HEAT SINK” the entire disclosure of which is hereby incorporated herein by reference, in its entirety, for all that it teaches and for all purposes.

### FIELD OF THE DISCLOSURE

Embodiments of the present disclosure relate generally to thermal solutions for computing hardware, and more specifically to cooling components used in a datacenter.

### BACKGROUND

As datacenters continue to operate at higher speeds (e.g., 100 Gb and beyond) and semiconductor dies grow larger in response to increased processing requirements, the thermal demands on the datacenter components increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires careful management; otherwise, components of the datacenter may fail under extreme thermal loads. For instance, processing units can generate heat during operation, which can result in reduced processing power and, in some cases, the failure of those processing units as well as the failure of system components connected thereto.

### GENERAL DESCRIPTION

As the data center infrastructure evolves, enhanced serviceability for the servers within a data center becomes more important. It is particularly important to address the challenges of assembly and disassembly required for servicing critical components on the baseboard. In a server baseboard, the components under the heat sink are often difficult to service as it may be necessary to remove the entire heat sink every time they are accessed. This problem is especially apparent when high-power components like a Graphics Processing Unit (GPU) or Central Processing Unit (CPU) are utilized. (The same is true of central processing unit (CPU) packages, parallel processing unit (PPU) packages, quantum processing unit (QPU) packages, and other processing unit packages. Throughout the present disclosure, it should be understood that references to CPUs, CPU packages, GPUs, and GPU packages apply also to other types of processing units and processing unit packages, respectively, including any other type of processing unit and processing unit package described herein.) Specifically, cooling these high-power components may require a relatively large surface for the heat sink. As a result, attaining a desired level of cooling may require using a large heat sink that blocks off a significant part of the board and prevents pluggable components from direct service.

One area where this problem is particularly apparent is for servicing the memory modules around the processing unit (e.g., GPU and/or CPU). A memory module (e.g., a Small Outline Compression Attached Memory Module (SOCAMM), a Dual In-Line Memory Module (DIMM), a network module, an optical module, a re-timer, and an Mid-Board Optical Module (MBOM)) may be a pluggable component but the heat sink of the processing unit may cover the memory modules, which means that the larger heat sink of the processing unit needs to be removed every time access to the memory module is desired. This configuration of components makes it extremely difficult to service the memory modules in the field.

Another approach that has been proposed to solve the above-noted problems is to provide one heat sink for the processing unit and a separate heat sink for each of the memory modules. Unfortunately, this approach may not provide enough surface area on the heat sink to adequately cool the processing unit due to high power density (e.g., the individual heat sink for the processing unit is too small to effectively remove heat from the processing unit). Even if such a heat sink is able to cool the processing unit, there will be a huge air temperature gradient downstream of the heat sinks between the processing unit and the memory module(s). This non-uniform air temperature downstream of the heat sinks makes it difficult or sometimes impossible to have sensitive components like GPUs or Peripherical Component Interconnect express (PCIe) form-factor cards downstream of these heat sinks. This is true for any similar application where there is a high-power component and a low-power, serviceable neighboring component on the board.

Embodiments of the present disclosure provide an approach to address the above-noted issues. One aspect of the present disclosure is to provide a split heat sink. In some embodiments, the heat sink is split into mechanically separate but thermally connected pieces, thereby providing a solution that is capable of conducting heat fairly between the individual pieces. The proposed approach provides a substantially uniform air temperature downstream of the heat sink avoiding large temperature gradients and enabling sensitive components downstream to operate effectively. Because of this conduction path, the individual pieces come together thermally and act as a single body from a heat transfer perspective although they can be assembled and disassembled separately. Aspects of the proposed solution thereby provide for relatively easy serviceability while also providing effective heat transfer capabilities. In other words, it becomes possible to service a pluggable component (e.g., a memory module) by simply removing a piece of the heat sink from the other piece or pieces of the heat sink without requiring disassembly of the other piece or pieces of the heat sink.

Aspects of the present disclosure include the ability to: enable effective cooling of high-power components (e.g., GPUs and/or CPUs) even after splitting the heat sink into multiple pieces which are independently serviceable; provide a way to have separate heat sinks for individual components yet cool them effectively; and enable extremely simple serviceability of pluggable components (e.g., a memory module) by simply removing a piece of the heat sink from the other pieces of the heat sink without requiring disassembly of the other pieces of the heat sink.

The present disclosure provides several advantages. First, in embodiments of the present disclosure a thermal connection is provided between heat sink parts, thus a heat transfer path between the individual heat sink pieces is provided that is not available in prior solutions. Second, embodiments of the present disclosure enable improved serviceability, including for pluggable components neighboring a processing unit and/or processing unit package. Third, embodiments of the present disclosure provide substantially uniform air temperature downstream of the high-power component (e.g., processing unit) and low-power components (e.g., SOCAMM, DIMM, network module, optical module, re-timer, MBOM). Fourth, embodiments of the present disclosure demonstrate a lower localized pressure drop since the fin pitch does not need to be aggressive to achieve efficient heat transfer. As a non-limiting example, the fin pitch may be at least 1.4 mm. Fifth, embodiments of the present disclosure exhibit a lower system pressure drop and have reduced complexity since ducting is not a requirement of the system to direct airflow towards the heat sink of the high-power component (e.g., processing unit). As a non-limiting example, the thermally-coupled heat sink sections may demonstrate a localized pressure drop of not more than 1.1 psi at 100 cfm without departing from the scope of the present disclosure. In some embodiments, the thermally-coupled heat sink sections may demonstrate a substantially constant pressure drop across their collective surfaces.

A heat sink according to embodiments of the present disclosure may comprise a first section to extract heat generated by a high-power component, and at least a second section, attachable to and detachable from the first section, to extract heat generated by a low-power component. The at least a second section, when attached to the first section, is thermally coupled to the first section such that the heat generated by the high-power component is further dissipated by the at least a second section.

A system according to other embodiments of the present disclosure may comprise a processing unit; a first memory module; a first heat sink section to extract heat generated by the processing unit; and a second heat sink section to extract heat generated by the first memory module, wherein the second heat sink section is attachable to and detachable from the first heat sink section, and wherein the first and second heat sink sections, when attached, collectively transfer heat from the processing unit.

A split heat sink according to still other embodiments of the present disclosure may be or comprise a central heat sink configured to extract heat generated by a processing unit; and a first side wing heat sink configured to extract heat generated by a memory module, the first side wing heat sink comprising at least one heat pipe and at least one fin; wherein the first side wing heat sink is removably attachable to the central heat sink and configured to also extract a portion of the heat generated by the processing unit when attached to the central heat sink.

In some embodiments, a heat sink is provided that includes: a first section to extract heat generated by a high-power component; and at least a second section, attachable to and detachable from the first section, to extract heat generated by a low-power component, wherein the at least a second section, when attached to the first section, is thermally coupled to the first section such that the heat generated by the high-power component is further dissipated by the at least a second section.

In some aspects, the high-power component includes at least one of a Graphics Processing Unit (GPU) and Central Processing Unit (CPU).

In some aspects, the low-power component includes a pluggable module. As an example, the memory module comprises at least one of a Small Outline Compression Attached Memory Module (SOCAMM), a Dual In-Line Memory Module (DIMM), a network module, an optical module, a re-timer, and an Mid-Board Optical Module (MBOM).

In some aspects, the low-power component is serviceable without detaching the high-power component from the first section.

In some aspects, the first section is attached to the at least a second section with one or more screws.

In some aspects, the at least a second section accommodates one or more heat pipes. As an example, the one or more heat pipes are thermally coupled with the first section and conduct heat from the first section into the at least a second section.

In some aspects, the first section and the at least a second section both include one or more finned structures.

In some aspects, the at least a second section includes a second section thermally coupled with a first low-power component and a third section thermally coupled with a second low-power component. In some aspects, the first section is positioned between the second section and the third section.

In some embodiments, a system is provided that includes: a processing unit; a first memory module; a first heat sink section to extract heat generated by the processing unit; and a second heat sink section to extract heat generated by the first memory module, where the second heat sink section is attachable to and detachable from the first heat sink section, and where the first and second heat sink sections, when attached, collectively transfer heat from the processing unit.

In some aspects the system may further include a Printed Circuit Board (PCB) that is attached to both the processing unit and the first memory module. In some aspects, the PCB carries electrical signals between the processing unit and the first memory module.

In some aspects the system may further include: a second memory module; and a third heat sink section to extract heat generated by the second memory module, where the third heat sink section is attachable to and detachable from the first heat sink section, and where the first and third heat sink sections, when attached, collectively transfer heat from the processing unit.

In some aspects, the first memory module is serviceable by detaching the first heat sink section from the second heat sink section.

In some aspects, the first heat sink section is attached to the second heat sink section with one or more screws.

In some aspects, the first heat sink section and the second heat sink section comprise a thermally-conductive material that includes at least one of: copper, aluminum, and an alloy thereof.

In some aspects the system further includes one or more heat pipes. In some aspects, the one or more heat pipes are embedded in a base of the second heat sink section. In some aspects, the first heat sink section includes a vapor chamber and the one or more heat pipes that are embedded in the base of the second heat sink section abut the vapor chamber of the first heat sink section.

In some aspects, the first heat sink section and the second heat sink section, when attached, substantially uniformly distribute heat generated by the processing unit and the memory module.

In some aspects, the processing unit includes at least one of a Graphics Processing Unit (GPU) and a Central Processing Unit (CPU).

In some aspects, the first memory module comprises at least one of a Small Outline Compression Attached Memory Module (SOCAMM), a Dual In-Line Memory Module (DIMM), a network module, an optical module, a re-timer, and an Mid-Board Optical Module (MBOM).

In some aspects the system may further include a stiffener base that provides structural support for the first heat sink section and that provides a connection interface between the first heat sink section and the second heat sink section.

In some aspects the system may further include a Thermal Interface Material (TIM). In some aspects, the TIM is provided between the stiffener base and the second heat sink section. In some aspects, the TIM is provided between the second heat sink section and the first memory module. In some aspects, the TIM includes at least one of a grease, a gap pad, a phase change material, and a putty, and wherein the TIM provides a substantially uniform cooling between the stiffener base, the first heat sink, and/or the second heat sink. In some aspects, the TIM accommodates a tolerance difference between the stiffener base, the first heat sink section, the second heat sink section, the processing unit, and/or the memory module.

In some embodiments, a split heat sink assembly is provided that includes: a central heat sink configured to extract heat generated by a processing unit; and a first side wing heat sink configured to extract heat generated by a memory module, the first side wing heat sink comprising at least one heat pipe and at least one fin; where the first side wing heat sink is removably attachable to the central heat sink and configured to also extract a portion of the heat generated by the processing unit when attached to the central heat sink.

In some aspects the split heat sink assembly further includes: a plurality of heat sink sections, each one of the heat sink sections mechanically connected to at least another one of the plurality of heat sink sections, where at least one of the plurality of heat sink sections is removable from the split heat sink assembly to facilitate access to an adjacent one of the plurality of heat sink sections.

In some aspects, the plurality of heat sink sections are thermally coupled so as to act as a single thermal unit.

In some aspects, the thermally coupled heat sink sections cause substantially uniform heating of surrounding air, such that air downstream of the thermally coupled heat sink sections has a substantially uniform air temperature.

In some aspects, heat transferred from the thermally coupled heat sink sections does not prevent sensitive components downstream of the thermally coupled heat sink sections from operating effectively.

In some aspects, removal of the at least one of the plurality of heat sink sections does not prevent the remaining ones of the plurality of heat sink sections from operating as a single thermal unit.

In some aspects, the thermally coupled heat sink sections include a plurality of finned structures having a fin pitch of at least 1.4 mm.

In some aspects, the thermally coupled heat sink sections demonstrate a localized pressure drop of not more than 1.1 psi at 100 cfm.

In some aspects, operation of the split heat sink assembly does not require ducting to achieve sufficient airflow through the plurality of finned structures.

In some aspects, the thermally coupled heat sink sections provide a substantially constant pressure drop

In some aspects, one of the plurality of heat sink sections is a central heat sink.

In some aspects, the central heat sink includes a vapor chamber configured to be in thermal communication with a processing unit or processing unit package.

In some aspects, the central heat sink comprises a vapor chamber configured to be in thermal communication with a high-powered component when in use.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a top perspective view of a split heat sink according to at least some embodiments of the present disclosure;

FIG. 2A is a side elevation view of a split heat sink according to at least some embodiments of the present disclosure, showing two side wing heat sinks separated from a central heat sink;

FIG. 2B is a bottom plan view of a split heat sink according to at least some embodiments of the present disclosure, showing two side wing heat sinks separated from a central heat sink;

FIG. 3A is a bottom plan view of a split heat sink according to at least some embodiments of the present disclosure, with one or more components removed to show details of the split heat sink;

FIG. 3B is a bottom plan view of a split heat sink according to at least some embodiments of the present disclosure, with one or more components removed to show details of the split heat sink;

FIG. 4 is a bottom perspective view of a split heat sink according to at least some embodiments of the present disclosure, with one or more components removed to show details of the split heat sink;

FIG. 5A is a top perspective view of two side wing heat sinks of a split heat sink according to at least some embodiments of the present disclosure;

FIG. 5B is a top perspective view of a central heat sink of a split heat sink according to at least some embodiments of the present disclosure;

FIG. 6 is a bottom perspective view of a heat pipe arrangement for a split heat sink according to at least some embodiments of the present disclosure;

FIG. 7 is a bottom perspective view of components of a split heat sink according to at least some embodiments of the present disclosure;

FIG. 8 is a side plan view of a split heat sink operably connected to a CPU and a plurality of memories according to at least some embodiments of the present disclosure;

FIG. 9 is a series of heat maps showing heat transfer results achieved using two different configurations of a split heat sink according to at least some embodiments of the present disclosure;

FIG. 10 is a block diagram illustrating a computer system according to at least some embodiments of the present disclosure;

FIG. 11 is a block diagram illustrating further details of a datacenter and components thereof according to at least some embodiments of the present disclosure;

FIG. 12 is a block diagram of a system according to at least some embodiments of the present disclosure;

FIG. 13 depicts a datacenter according to at least some embodiments of the present disclosure;

FIG. 14 depicts a liquid-cooled server rack according to at least some embodiments of the present disclosure;

FIGS. 15A-15D depict block diagrams showing aspects of a neural network-enabled approach to liquid cooling of racks at a data center level according to at least some embodiments of the present disclosure;

FIG. 16 depicts a block diagram of a system according to at least some embodiments of the present disclosure; and

FIG. 17 depicts a block diagram of a computing environment according to at least some embodiments of the present disclosure.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure may be deployed in any number of environments, including a datacenter environment or any other suitable environment that requires the management of thermal loads generated by computing components.

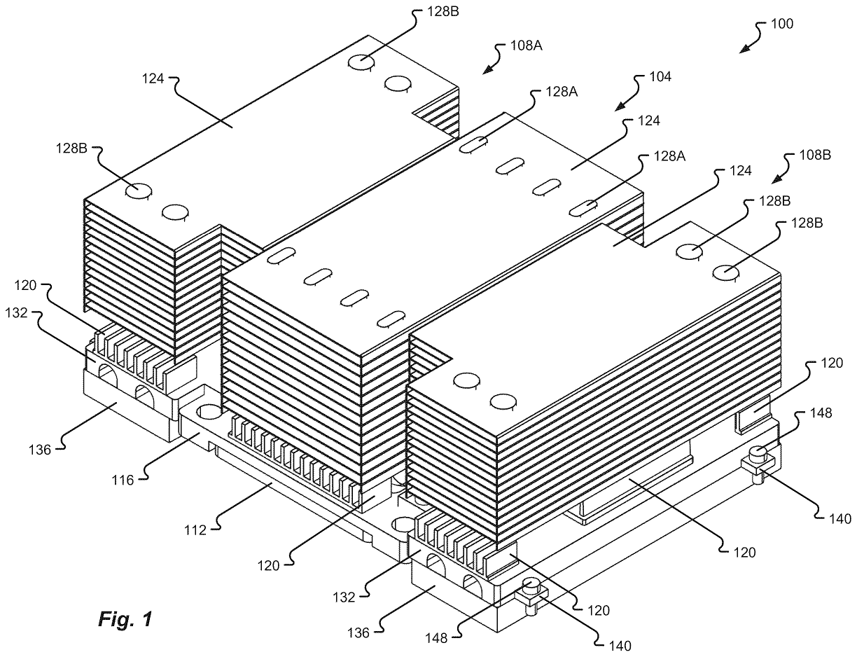

Split heat sinks according to embodiments of the present disclosure, as well as illustrative datacenter environments and components useful for fully understanding the present disclosure, are shown and will now be described with reference to FIGS. 1 through 17.

FIGS. 1-8 depict various aspects of a split heat sink 100 according to embodiments of the present disclosure, and although portions of the following description may refer to a specific figure in describing a particular aspect of the split heat sink 100, the same or similar components may be depicted in other ones of the FIGS. 1-8.

With general reference to FIGS. 1-8 and specific reference to FIG. 1, the split heat sink 100 comprises a central heat sink 104, a first side wing heat sink 108A, and a second side wing heat sink 108B. Throughout this disclosure, the central heat sink 104 may be referred to, for example, as a first section or a first heat sink section, and each of the first and second side wing heat sinks 108A, 108B may be referred to, for example, as a second section, a second heat sink section, a third section, and/or a third heat sink section. The first side wing heat sink 108A and the second side wing heat sink 108B are each individually detachable from the central heat sink 104, thus facilitating the servicing of computing hardware (including, for example, memory modules) positioned underneath one or both of the side wing heat sinks 108A and/or 108B. As further shown and described herein, however, when the first and second side wing heat sinks 108A and 108B are attached or connected to the central heat sink 104, each side wing heat sink 108A, 108B is thermally coupled to the central heat sink 104, and the split heat sink 100 provides integrated cooling for a processing unit, processing unit package, or other high-power component operably connected to the central heat sink 104 while also providing cooling for the memory module or other low-power component operably connected to each of the side wing heat sinks 108A, 108B.

The phrase “thermally coupled,” as used herein, refers to two or more objects being connected in a way that facilitates heat transfer between the two objects, such that the two or more objects act as a single body (or as a substantially single body) from a heat transfer perspective. A “low-power component” within the meaning of the present disclosure includes any component that draws relatively less power (and as a result generates relatively less heat) than a CPU, GPU, or other processing unit or processing unit package on a motherboard, mainboard, blade, node, or other computing device. Thus, for example, a low-power component may be or include a random-access (or similar) memory unit (including any memory unit described herein), a chipset or platform controller hub, a high-speed interconnect, a baseboard management controller, a storage controller, a voltage regulator, and/or a power delivery circuit. In some embodiments, a low-power component may be or include any component that draws less than about 100 W of power during operation.

Although shown in FIGS. 1-8 as comprising a first section (e.g., the central heat sink 104), a second section (e.g., the first side wing heat sink 108A), and a third section (e.g., the second side wing heat sink 108B), split heat sinks according to embodiments of the present disclosure may comprise only a first section and a second section, with one configured to cool a high-powered component and the other configured to primarily cool a low-powered component while aiding in the cooling of the high-powered component. In other embodiments, a split heat sink may comprise more than three sections. For example, a split heat sink according to embodiments of the present disclosure may comprise four sections, or five sections, or six sections, or more sections. In such embodiments, the first section may be configured to extract heat generated by a high-powered component, and each of the remaining sections may be configured to extract heat generated by a separate, low-power component. Also in such embodiments, each of the sections configured to extract heat generated by a separate, low-power component may also be configured to aid in the dissipation of heat generated by the high-power component to which the first section is operably attached, in substantially the same manner as described herein with respect to the second and third sections.

Embodiments of the present disclosure that utilize more than three sections may utilize a variety of arrangements of each section. For example, in embodiments with four or five sections, each of the second, third, fourth, and (where present) fifth sections may be arranged adjacent one side of the substantially square or rectangular first section. In embodiments with six sections, the first section may have a substantially pentagonal shape, and each of the second through sixth sections may be arranged adjacent one side of the first section. In embodiments with seven sections, the first section may have a substantially hexagonal shape, and each of the second through seventh sections may be arranged adjacent one side of the first section.

Alternatively, additional sections beyond a third section may be secured adjacent to the second and third sections (e.g., in a manner that increases the length of the split heat sink but not its width, or in a manner that increases the width of the split heat sink but not its length). In still other embodiments, split heat sinks comprising more than three sections may be configured such that the second and any additional sections each comprises at least a portion that extends to and is thermally coupled with the first section, even though such portion may not be in substantially direct contact with an entire edge of the first section.

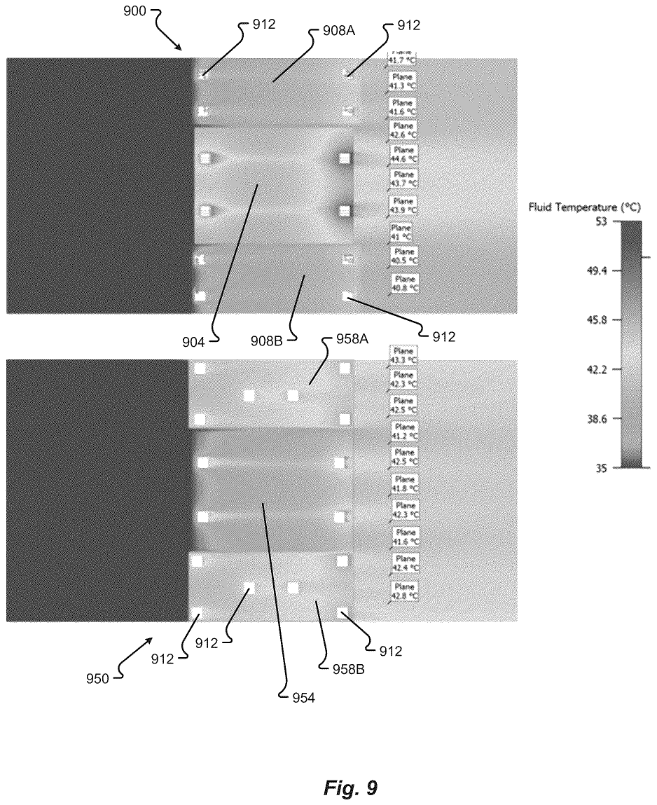

The central heat sink 104 comprises a vapor chamber 112 configured to be in thermal communication (whether through direct contact or otherwise) with a processing unit (e.g., a CPU or GPU), a processing unit package, or another high-powered component when in use. A stiffener base 116 is mounted over and partially surrounds the vapor chamber 112 to provide structural support for the components of the central heat sink 104 and ensure that the weight of the central heat sink 104 does not rest on the processing unit or other high-powered component to which the central heat sink 104 is mounted (e.g., the CPU 804 shown in FIG. 8).

Each heat sink section of the split heat sink 100 comprises one or more finned structures. More specifically, one or a plurality of vertical fins 120 may be mounted to the stiffener base 116, and one or a plurality of horizontal fins 124 may be stacked with even or irregular vertical spacing above the stiffener base 116. One or more heat pipes 128A may also be embedded in and/or mounted to the stiffener base 116 and extend up through the horizontal fins 124 to transfer heat to those horizontal fins 124.

Each of the side wing heat sinks 108A, 108B comprises a side wing base 132 that, similarly to the stiffener base 116, provides structural support for the components of the respective side wing heat sink 108A or 108B and helps to ensure that the weight of the side wing heat sink 108A or 108B does not rest on the memory module or other component to which the side wing heat sink 108A or 108B is thermally coupled (e.g., the memory modules 808A, 808B shown in FIG. 8). Each side wing base 132 may comprise one or more mounting tabs 140, each having a mounting hole 144 therein, configured to receive a removable mounting fastener 148 (e.g., a screw, a bolt, a pin) that secures the side wing base 132 to a printed circuit board (PCB) to which the components being cooled are connected (e.g., PCB 812, shown in FIG. 8) and/or to a rack or other structural element of a datacenter. The mounting tabs 140 may be integrally formed with the side wing base 132, or formed separately from the side wing base 132 and subsequently attached thereto using any known joining method (e.g., mechanical fasteners, welding, bonding).

Each side wing base 132 may also comprise one or more mounting holes 144 within the side wing base 132 itself, each configured to receive a removable mounting fastener 148 that secures the side wing base 132 to the stiffener base 116 of the central heat sink 104. The use of removable mounting fasteners 148 to secure the side wing bases 132 (and thus the side wing heat sinks 108A, 108B) to the central heat sink 104 and/or to an underlying substrate (e.g., a PCB) enables the side wing heat sinks 108A, 108B to be attachable to and detachable from the central heat sink 104 and/or the underlying substrate, thus facilitating removal of the side wing heat sinks 108A, 108B independently of the central heat sink 104.

The side wing bases 132 may be formed of copper, aluminum, a copper alloy, an aluminum alloy, another metal, and/or another metal alloy. A material and/or a thickness of the side wing bases 132 may be selected to ensure sufficient structural rigidity of the side wing heat sinks 108A, 108B. The side wing bases 132 comprise a plurality of heat pipe cutouts 134, which are configured to secure the heat pipes 128B so that a flat bottom surface thereof is in direct contact (or otherwise thermally coupled) with the vapor chamber 112 when the side wing heat sinks 108A, 108B are mounted to the central heat sink 104, and also so that the flat bottom surface thereof is thermally coupled (e.g., through the thermal interface material 136) to a low-power component (e.g., a memory 808A, 808B) that the side wing heat sinks 108A, 108B are intended to cool.

A thermal interface material 136 enhances thermal conductivity and ensures thermal coupling between the memory modules 808A, 808B or other low-power component operably connected to each of the side wing heat sink 108A, 108B. In some embodiments, the thermal interface material 136 may be, for example, a gap pad (rather than, for example, phase change material). Use of a gap pad rather than a phase change material simplifies the servicing process because the gap pad is easier to remove and replace, reducing the complexity of maintenance and thus also reducing the time required for maintenance.

A plurality of vertical fins 120 may be mounted to an upper surface of the side wing base 132, either directly or via a thermal interface material such as the thermal interface material 136. In some embodiments, additional thermal interface material 136 may be utilized between the stiffener base 116 and the vertical fins 120 of the central heat sink 104. The thermal interface material 136 may include any suitable type of thermal interface material (TIM), which may include, for example, a thermal grease, a gap pad, a phase change material, a thermal putty, combinations thereof, and the like. In some embodiments, the thermal interface material 136 may be compliant (e.g., compressible and/or soft) to help take up tolerance differences between at least one of the stiffener base 116, the first heat sink section 104, the second heat sink section(s) 108, the processing unit 804, and/or the memory module 808. The thermal interface material 136 may also be configured to provide substantially uniform cooling between components, as if the two components were physically contacting one another.

One or more heat pipes 128B may be mounted to and/or embedded in each side wing base 132. The heat pipes 128B are configured to extend upward through a plurality of horizontal fins 124, which may be stacked above the side wing base 132 with even or irregular vertical spacing along a height of the heat pipes 128B.

The vertical fins 120 utilized in the central heat sink 104 and in the first and second side wing heat sinks 108A, 108B may be manufactured from copper, aluminum, another metal, and/or any metal alloy. The thickness of each vertical fin 120, the spacing between any two vertical fins 120, as well as the length and height of each vertical fin 120 (or, alternatively, a surface area of each horizontal fin 124) may be selected to provide a desired level of heat dissipation. Additionally, the vertical fins 120 may be oriented on the stiffener base 116 and the side wing bases 132 so that air flowing past the split heat sink 100 passes between the individual vertical fins 120 and along the length of each vertical fin 120.

Similarly, the horizontal fins 124 utilized in the central heat sink 104 and the first and second side wing heat sinks 108A, 108B may be manufactured from copper, aluminum, another metal, and/or any metal alloy. The thickness of each horizontal fin 124, the spacing between any two horizontal fins 124 (e.g., the pitch of the horizontal fins 124), as well as the length and width of each horizontal fin 124 (or, alternatively, the surface area of each horizontal fin 124) may be selected to provide a desired level of heat dissipation.

The ability to thermally couple the side wing heat sinks 108A, 108B to the central heat sink 104, as described in the present disclosure, beneficially enables a coarser pitch between adjacent horizontal fins 124 on the various sections of the split heat sink 100 than would be possible if only the central heat sink 104 were used to extract and dissipate heat from a high-power component thermally coupled thereto. This beneficially results in a lower pressure drop across the heat sink, requiring less powerful fans to maintain a constant flow of air through the heat sink and reducing cost, complexity, and energy consumption of the overall cooling system.

In some embodiments, opposite edges of one or more horizontal fins 124 of the first, second, and/or third heat sink sections 104, 108A, and 108B, respectively may be bent downward (e.g., toward the next lower horizontal fin 124) or upward (e.g., toward the next higher horizontal fin 124) to ensure that air flowing between adjacent horizontal fins 124 passes along a length of the split heat sink 100. For example, on the first and second side wing heat sinks 108A, 108B, an edge of the horizontal fins 124 that is proximate the central heat sink 104 may be bent upward or downward as described, and the opposite edge of the same horizontal fins 124 may also be bent upward or downward as described. Similarly, on the central heat sink 104, an edge of the horizontal fins 124 facing the first side wing heat sink 108A may be bent upward or downward as described, and the opposite edge of the same horizontal fins 124 (e.g., the edge facing the second side wing heat sink 108B) also may be bent upward or downward as described.

The heat pipes 128A and 128B may be any type of heat pipe suitable for use with computing and/or datacenter hardware and may have the same or a different cross-sectional shape. In some embodiments, each heat pipe 128A and/or 128B may be made of copper, aluminum, or another metal or metal alloy, and may comprise a sealed chamber with a working fluid (e.g., water, ammonia, methanol, ethanol) disposed therein. The heat pipes 128A and 128B are configured to transfer heat generated by the computing components being cooled by the split heat sink 100 (e.g., a CPU 804, one or more memory modules 808A, 808B) up and into the horizontal fins 124, which are configured to absorb heat from the heat pipes and dissipate that heat (e.g., through convection to air or another fluid flowing over and past the horizontal fins 124). When the side wing heat sinks 108A, 108B are attached to the central heat sink 104, the heat pipes 128B in the side wing heat sinks 108A, 108B are thermally coupled with the vapor chamber 112 and are configured to conduct heat from the first heat sink section (e.g., the central heat sink 104) into the second and third heat sink sections (e.g., the side wing heat sinks 108A, 108B) for improved dissipation of heat generated by the high power component operably connected to the first heat sink section. In some embodiments, more or fewer heat pipes 128A, 128B may be accommodated within the central heat sink 104 and the side wing heat sinks 108A, 108B, respectively, and/or may have a different configuration within the central heat sink 104 and the side wing heat sinks 108A, 108B, respectively.

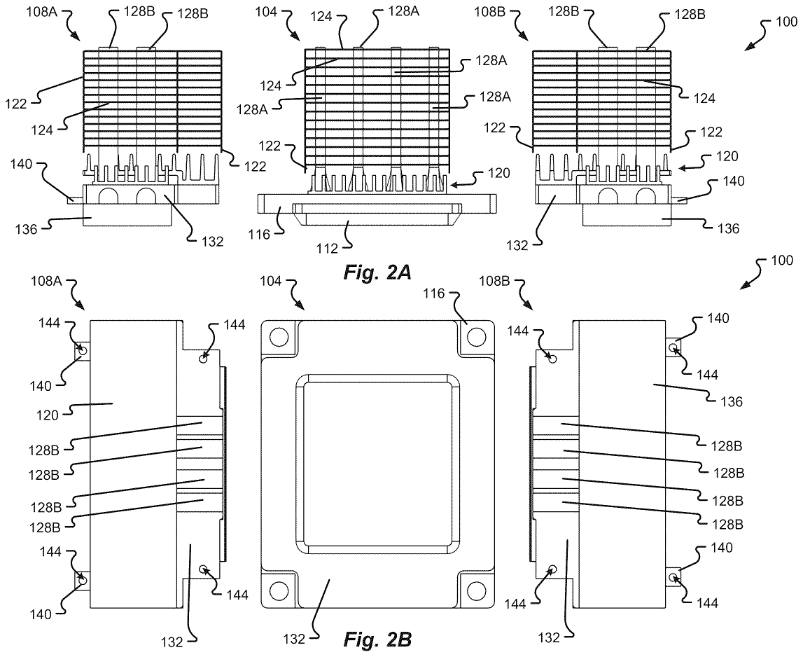

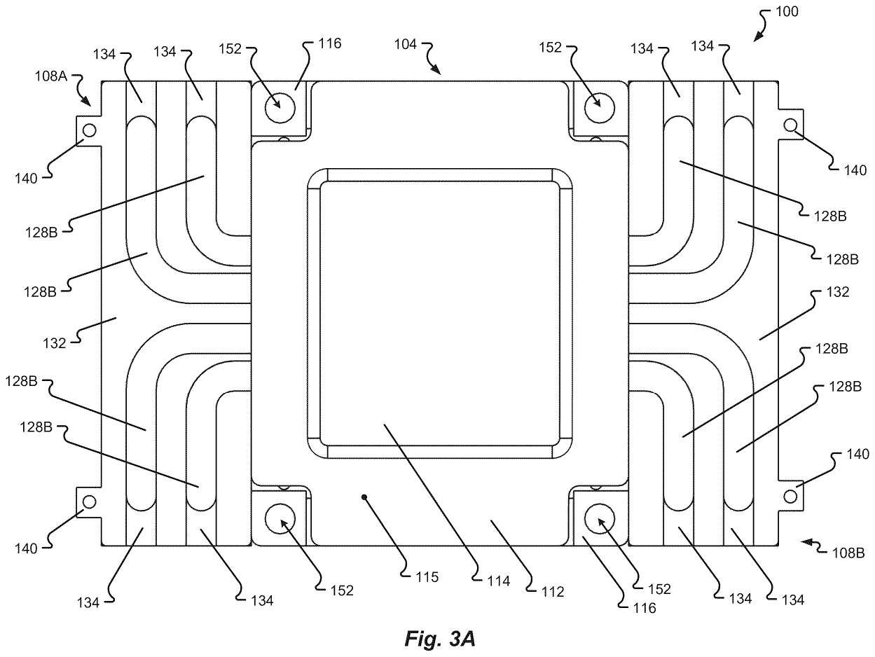

With reference now to FIGS. 2A and 2B, each of the side wing heat sinks 108A, 108B may be independently attached to and detached from the central heat sink 104, from a PCB to which the split heat sink 100 is mounted (e.g., a PCB 812), and/or from a rack or other datacenter structural component to which the split heat sink 100 is mounted. Detachment may be achieved by removing mounting fasteners (e.g., screws, bolts, pins) such as the mounting fasteners 148 from the mounting holes 144 positioned proximate the corners of the side wing heat sink 108A or 108B. As noted above, in some embodiments, two of the mounting holes 144 are positioned in the side wing base 132, and two of the mounting holes 144 are positioned in mounting tabs 140 extending from the side wing base 132. However, the mounting holes 144 may be arranged differently in different embodiments, and different embodiments may have more or fewer mounting holes 144.

Still with general reference to FIGS. 1-8 but as specifically shown in FIG. 2A, opposite edges 122 of each horizontal fin 124 of the central heat sink 104 and the side wing heat sinks 108A, 108B are bent downward so as to contact or nearly contact the next lower horizontal fin 124 (or, for the lowest horizontal fin 124, such that opposite edges 122 of the horizontal fin 124 extend downward toward the stiffener base 116 or the side wing base 132). As a result, the stacked horizontal fins 124 form essentially closed passageways for air flowing therethrough, helping to direct airflow in the same direction and ensure that air passes over an entirety of the surface of each horizontal fin 124. As also shown in FIG. 2A, all of the vertical fins 120 and horizontal fins 124 are arranged to facilitate air flow in the same direction through the split heat sink 100.

In embodiments of the present disclosure comprising more than three sections, the alignment of the vertical fins 120 and configuration of the horizontal fins 124 (and specifically of the bent edges 122 of the horizontal fins 124) on given section may be configured differently than on another section, so that when each of the second and additional sections are attached to the first section, the entire split heat sink is configured to direct airflow therethough in the same direction.

Referring generally to FIGS. 1-8, and specifically as shown in FIG. 2B, the heat pipes 128B of each side wing heat sink 108A, 108B extend through the heat pipe cutouts 134 in the side wing base 132 toward the vapor chamber 112 of the central heat sink 104. When the side wing heat sinks 108A, 108B are attached to the central heat sink 104, a portion of each heat pipe 128B abuts the vapor chamber 112, thus facilitating the transfer of heat from the vapor chamber 112 to the horizontal fins 124 of the side wing heat sinks 108A, 108B. The thermal interface material 136 positioned underneath each side wing heat sink 108A, 108B also facilitates heat transfer from a memory module (e.g., a memory module 808A, 808B) or other low-power computing component operably connected to the side wing heat sinks 108A, 108B to the heat pipes 128B of the side wing heat sink 108A or 108B, which allows that heat to be transferred to the horizontal fins 124 of the side wing heat sink 108A or 108B for dissipation to the surrounding air or other fluid.

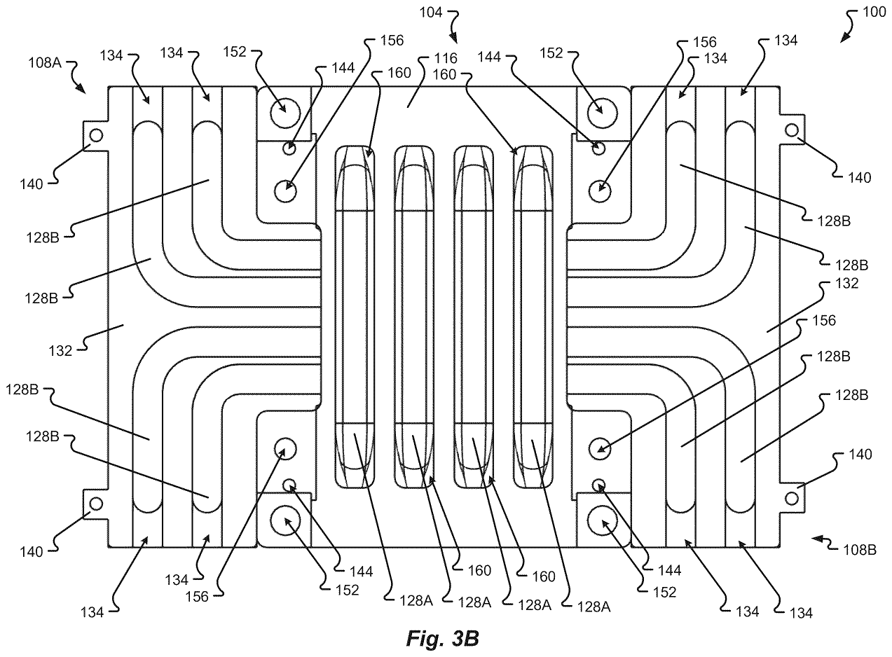

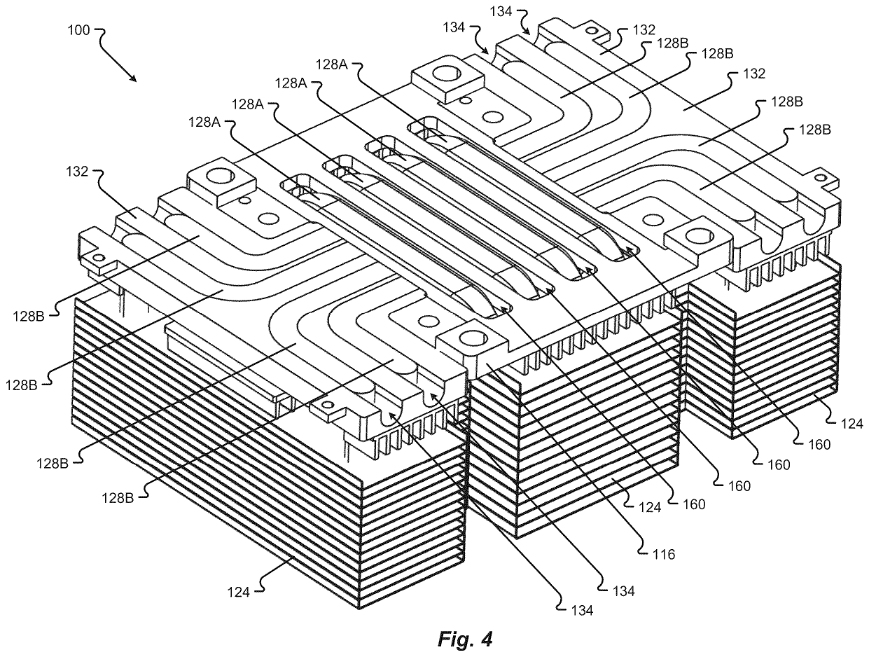

FIG. 3A depicts a bottom view of a split heat sink 100 according to at least some embodiments of the present disclosure, with the thermal interface material 136 of each side wing heat sink 108A, 108B removed. With the thermal interface material 136 removed, the arrangement of the heat pipes 128B is more readily visible. As can be seen, the heat pipes 128B are configured to maintain substantial surface area in contact with the thermal interface material 136 positioned thereon, thus facilitating heat transfer from the thermal interface material 136 to the heat pipes 128B. Also visible in FIG. 3A are the cutouts 134 in the side wing bases 132 in which the heat pipes 128B are embedded.

The stiffener base 116 comprises four holes 152 each configured to receive a mechanical fastener that secures the central heat sink 104 of the split heat sink 100 to an underlying PCB (e.g., the PCB 812) and/or to a rack or other structural element of a datacenter. In other embodiments, the stiffener base 116 may comprise more or fewer than four holes for this purpose.

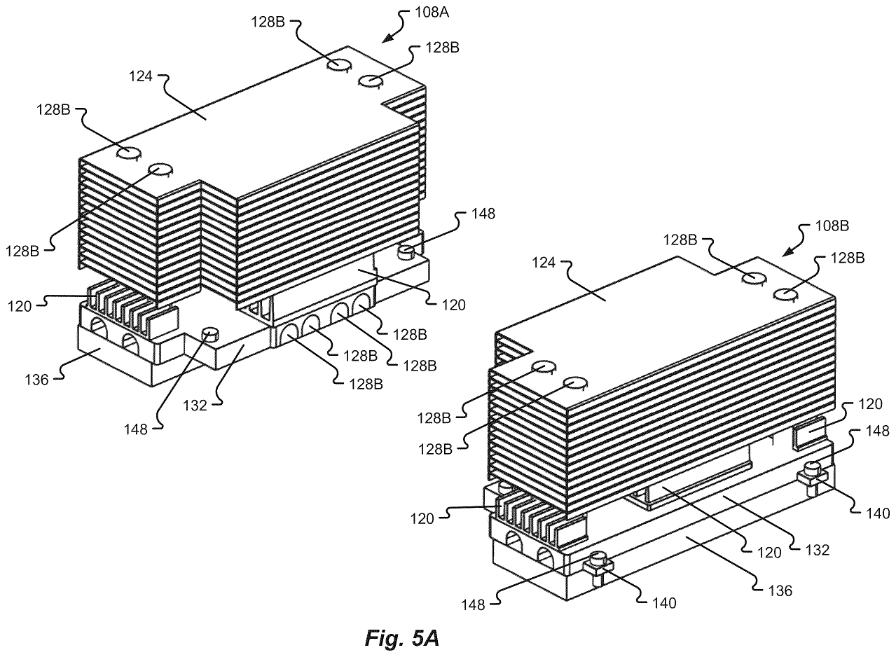

FIGS. 3B and 4 show another bottom view of a split heat sink 100 according to at least some embodiments of the present disclosure, with the vapor chamber 112 removed from the central heat sink 104 as well as the thermal interface material 136 of each side wing heat sink 108A, 108B removed. In this view, the portions of the heat pipes 128B in direct contact with the vapor chamber 112 are visible, as are the bottom surfaces of the heat pipes 128A that are also in direct contact with the vapor chamber 112 during operation of the split heat sink 104. In some embodiments, thermal interface material such as the thermal interface material 136 may be used to fill any gaps between the heat pipes 128A and the vapor chamber 112, and/or to ensure the thermal coupling of the heat pipes 128A and the vapor chamber 112. The heat pipes 128A are visible through the cutouts 160 in the stiffener base 116, which they heat pipes 128A are embedded. The cutouts 160 may be configured to receive the heat pipes 128A with a minimal gap or no gap between each heat pipe 128A and adjacent walls of the corresponding cutout 160, so as to enable and improve heat transfer (e.g., through conduction) from the stiffener base 116 to the heat pipes 128A. Each of the heat pipes 128A has a flat bottom surface to increase the amount of surface area in contact with the vapor chamber 112 and/or the thermal interface material 136, and thus improve heat transfer into the heat pipes 128A and through the heat pipes 128A to the horizontal fins 124.

With the vapor chamber 112 removed, also visible in the stiffener base 116 are the holes 144 used to secure the side wing heat sinks 108A, 108B to the central heat sink 104, as well as the holes 156 used for mounting the vapor chamber 112 to the stiffener base 116 (or vice versa). In various embodiments of the present disclosure, the vapor chamber 112 may be mounted to the stiffener base 116 using mechanical fasteners (e.g., screws, bolts, pins, rivets), adhesive, thermal interface material, and/or any other suitable mounting system, material, and/or method. Where mechanical fasteners are used, the mechanical fasteners may be the same as or similar to the mechanical fasteners 148 described herein. Additionally, in some embodiments the number of holes 144 and 156 in the stiffener base 116 may be more or fewer than four.

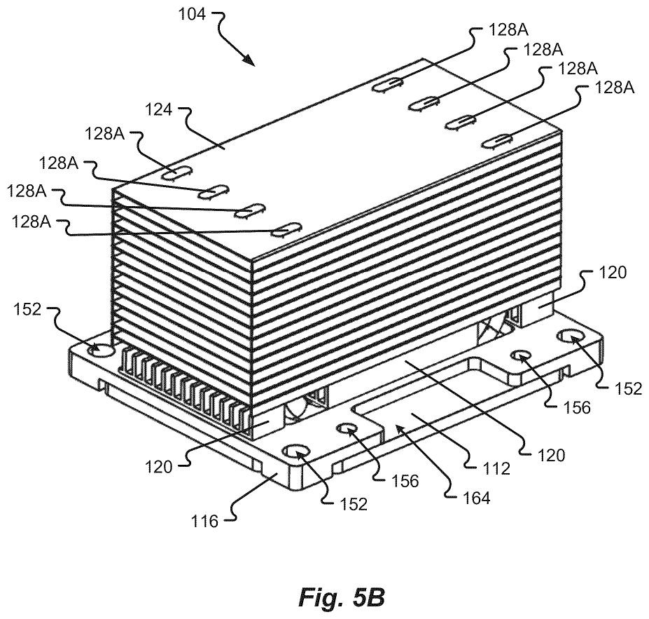

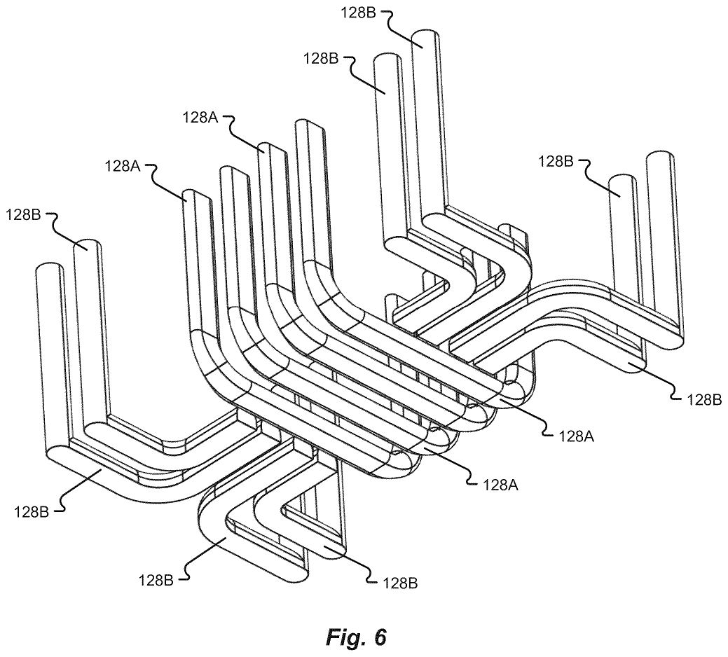

As can be seen in the perspective views of FIGS. 5A and 5B, the stiffener base 116 comprises a side cutout 164 that exposes a portion of the upper surface of the vapor chamber 112 and forms a connection interface for the side wing heat sinks 108A, 108B. More specifically, side cutouts 164 receive a portion of the first and second side wing heat sinks 108A, 108B (e.g., a portion of the side wing base 132 of each side wing heat sink 108A, 108B), such that a portion of a bottom surface of each of the heat pipes 128B abuts the exposed upper surface of the vapor chamber 112 when the side wing heat sinks 108A, 108B are secured to the central heat sink 104. In some embodiments, the bottom surface of each of the heat pipes 128B may be in direct contact with the vapor chamber 112 (e.g., with the portion of the upper surface of the vapor chamber 112 exposed by the side cutouts 164). In other embodiments, a thermal interface material 136 may be positioned between the heat pipes 128B and the vapor chamber 112 to ensure thermal coupling between those components and to facilitate heat transfer from the vapor chamber 112 to the heat pipes 128B. Thermal interface material such as the thermal interface material 136 may be utilized between any two components of the split heat sink 100 as described herein to improve thermal coupling between such components, regardless of whether the components are permanently or removably secured to or proximate each other.

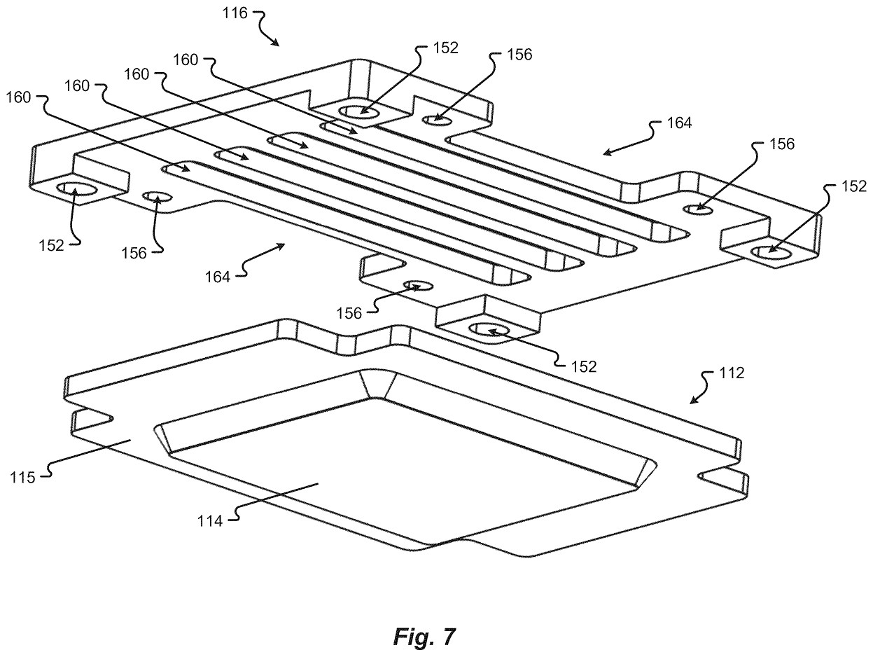

FIG. 6 depicts just the heat pipes 128A, 128B of the split heat sink 100, which are carefully configured and arranged to extract heat from the vapor chamber 112 and transfer that heat through the horizontal fins of the central heat sink 104 and the side wing heat sinks 108A, 108B. As a result, the split heat sink 100 is able to provide sufficient cooling to the processing unit (e.g., the CPU 804) being cooled by the split heat sink 100, while still enabling the side wing heat sinks 108A, 108B to be removed to facilitate servicing of the low-power computing component(s) thereunder (e.g., the memory modules 808A, 808B). Additionally, the heat pipes 128B are configured to receive heat from those same low-power computing components (e.g., the memory modules 808A, 808B) and transfer that heat, in addition to the heat received from the vapor chamber 112, to the horizontal fins 124 of the side wing heat sinks 108A, 108B.

Although FIG. 6 (and, more generally, FIGS. 1-8) depict a specific configuration of heat pipes 128A and 128B, embodiments of the present disclosure include other heat pipe configurations. In some embodiments, one or more of the first section (e.g., the central heat sink 104), the second section (e.g., the first side wing heat sink 108A), and the third section (e.g., the second side wing heat sink 108B) comprises only a single heat pipe 128A or 128B. Also in some embodiments, one or more of the first, second, and third sections comprises fewer or more heat pipes 128A, 128B than depicted in FIGS. 1-8. Additionally, regardless of whether the first, second, and/or third sections comprise the same or a different number of heat pipes 128A, 128B, those heat pipes may be arranged or configured differently than as shown in FIG. 6. In some embodiments, one or more heat pipes 128A in the central heat sink 104 may have a different cross-section than one or more other heat pipes 128A in the central heat sink 104. Also in some embodiments, one or more heat pipes 128B in either or both of the first and second side wing heat sinks 108A, 108B may have a different cross-section than one or more other heat pipes 128B in the same heat sink section.

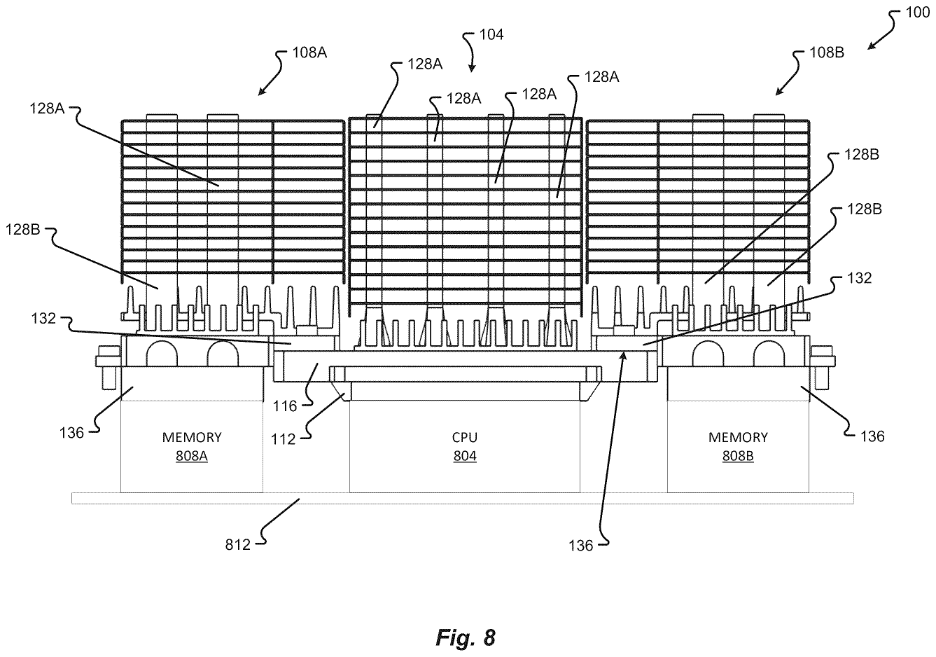

With continued general reference to FIGS. 1-8, and specifically with reference to FIG. 7, the vapor chamber 112 may be, for example, a heat transfer device with a fluid inside that alternately evaporates and condenses to quickly spread heat over the surface area of the vapor chamber 112. The vapor chamber 112 may be formed of copper, a copper alloy, another metal or metal alloy, or another thermally conductive material. In some embodiments, the vapor chamber 112 may comprise a sealed chamber 114 with a working fluid contained therein. The working fluid may be, for example, water, ammonia, methanol, or ethanol. The sealed chamber 114 may extend below a bottom surface 115 of the vapor chamber 112. The sealed chamber 114 may be shaped so as to fit precisely over the entirety of a processing unit or processing unit package, such as the CPU 804.

The stiffener base 116 may be formed of copper, aluminum, a copper alloy, an aluminum alloy, another metal, and/or another metal alloy. A material and/or a thickness of the stiffener base 116 may be selected to ensure sufficient structural rigidity of the central heat sink 104 and/or of the entire split heat sink 100. The stiffener base 116 comprises a plurality of heat pipe cutouts 160, which are configured to secure the heat pipes 128A so that a flat bottom surface thereof is in direct contact with the vapor chamber 112 when the vapor chamber 112 is mounted to or within the stiffener base 116 (or vice versa). The stiffener base 116 also comprises one or more side cutouts 164 that expose a portion of an upper surface of the vapor chamber 112 (opposite the bottom surface 115) to allow efficient heat transfer from a high-power component thermally coupled the vapor chamber 112 to the heat pipes 128B of the side wing heat sinks 108A, 108B.

FIG. 8 depicts a side view of a heat sink 100 according to at least some embodiments of the present disclosure, arranged in an operational configuration with (e.g., thermally coupled to) a CPU 804, a memory module 808A, and a memory module 808B, each of which is mounted to a PCB 812. The PCB 812 carries electrical signals between or among the CPU 804, the memory module 808A, and/or the memory module 808B. As shown in FIG. 8, the CPU 804 is in direct contact with the vapor chamber 112 (although, in some embodiments, a thermal interface material such as the thermal interface material 136 may be utilized to ensure thermal coupling between the CPU 804 and the vapor chamber 112). Similarly, a portion of the side wing base 132 of each side wing heat sink 108A, 108B is received into the side cutouts 164 (not visible in FIG. 8) of the stiffener base 116, which in turn allows the heat pipes 128B of the side wing heat sinks 108A, 108B to contact the vapor chamber 112 and transfer heat away from the vapor chamber 112.

If an operator of a datacenter comprising the CPU 804, the memory modules 808A, 808B, and the heat sink 100 needs to replace or otherwise service, for example, the memory module 808A, the split heat sink 100 according to embodiments of the present disclosure would allow the operator to detach just the side wing heat sink 108A from central heat sink 104 and/or from the PCB 812, remove the side wing heat sink 108A, remove the memory module 808A, install the memory module 808A post-service (or install a new memory module 808A), and re-attach the side wing heat sink 108A to the central heat sink 104 and/or to the PCT 812, all without having to uninstall (and subsequently reinstall) the remainder of the split heat sink 100. Substantially the same procedure could be utilized to service the memory module 808B by detaching and then re-attaching just the second side wing heat sink 108B. As a result, embodiments of the present disclosure facilitate improved serviceability, reduced wear on computing components (resulting, for example, from repeating installation/uninstallation cycles), and less down time for data center operators, thus reducing costs, maintenance efforts and improving performance.

The CPU 804 represents any suitable processing unit, processing unit package, or other high-power component that might be utilized, for example, in a datacenter environment, including any processing unit, processing unit package, and/or high-power component described herein. For the avoidance of doubt, the CPU 804 may represent, for example, a GPU, a Quantum Processing Unit (QPU), a Parallel Processing Unit (PPU), an Application-Specific Integrated Chip (ASIC), and/or any other processing unit or similar silicon package that generates heat during use.

Each of the memory modules 808A, 808B represents a memory module or other low-power component that might be utilized, for example, in a datacenter environment, and that might be operably connected to the CPU 804 (or other processing unit, processing unity package, or high-power component) via a PCB 812. The memory modules 808A, 808B may be, for example, a Small Outline Compression Attached Memory Module (SOCAMM); a High Bandwidth Memory (HBM); a Hybrid Memory Cube (HMC); a Dual In-Line Memory Module (DIMM); a network module; an optical module; a re-timer; a Mid-Board Optical Module (MBOM); any other memory, memory module, or low-power component described herein; and/or any other memory module or low-power component.

Although the present disclosure discusses the use of a split heat sink such as the split heat sink 100 with a processing unit and one or more memories, split heat sinks according to embodiments of the present disclosure may be utilized in any application requiring cooling of a high-powered component and one or more neighboring lower-powered components.

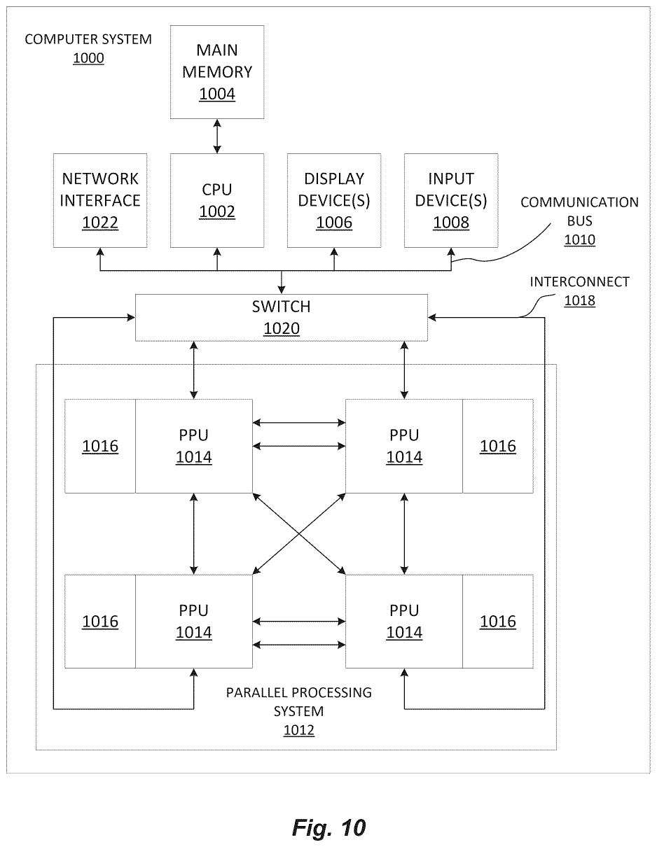

FIG. 9 illustrates a heat map showing two different split heat sink configurations similar to the heat sink 100 described above during use. The first configuration utilizes a split heat sink 900 (substantially similar to the heat sink 100 of FIGS. 1-8) having a central heat sink 904, two side wing heat sinks 908A, 908B, and a plurality of heat pipes 912 (e.g., for transferring heat from computing components underneath the split heat sink 900 to horizontal fins such as the horizontal fins 124). The second configuration utilizes a split heat sink 950 (also substantially similar to the heat sink 100 of FIGS. 1-8) having a central heat sink 954, two side wing heat sinks 958A, 958B, and a plurality of heat pipes 912 (e.g., for transferring heat from computing components underneath the split heat sink 950 to horizontal fins such as the horizontal fins 124). The split heat sink 900 and the split heat sink 950 differed from each other in their arrangement of the heat pipes 912, with the split heat sink 950 comprising two extra heat pipes rising through the horizontal fins of the side wing heat sinks 958A, 958B.

As evident from FIG. 9, the design of the split heat sinks 900, 950 allows a uniform heat distribution between the CPU heat sink (e.g., the central heat sinks 904, 954) and the side wing heat sinks (e.g., the side wing heat sinks 908A, 908B, 958A, 958B). Even for the worst-case tolerance stack-up on the side wing heat sinks, where one side wing heat sink is the tallest possible and the other is the shortest possible (e.g., due to manufacturing errors in manufacturing/assembling the side wing heat sinks), the temperature distribution downstream of the heat sink is still relatively uniform. In the test that yielded the heat maps depicted in FIG. 9, there was a height difference of 0.6 mm between the two side wings, resulting in a thermal interface material layer between one side wing (e.g., the side wing heat sink 908A, 958A) and the central heat sink (e.g., the central heat sink 904, 954) being 1.3 mm thick, and a thermal interface material layer between the other side wing (e.g., the side wing heat sink 908B, 958B) and the central heat sink (e.g., the central heat sink 904, 954) being 0.7 mm thick. The results shown in FIG. 9 were also obtained notwithstanding the non-uniformity in and tolerances of the thermal interface material itself.

To achieve the results depicted in FIG. 9, a 300W CPU was used under the central heat sink 904, 954, and a 40W SOCAMM module was used under each side wing heat sink 908A, 908B, 958A, 958B. The inlet air temperature was 35 degrees Celsius, and the air flow rate through the split heat sinks 900, 950 was 75 cubic feet per minute. For the split heat sink 900, the air temperature across the length of the split heat sink (e.g., from one end of the side wing heat sink 908A to an opposite end of the side wing heat sink 908B) had a maximum variation of 4.1 degrees Celsius (ranging from 40.5 to 41.6 degrees Celsius). For the split heat sink 950, the air temperature across the length of the split heat sink (e.g., from one end of the side wing heat sink 958A to an opposite end of the side wing heat sink 958B) had a maximum variation of 2.1 degrees Celsius (ranging from 41.2 to 43.3 degrees Celsius). These results demonstrate that uniform heat spreading between the side wings of the split heat sink according to embodiments of the present disclosure can be achieved even with undesirable tolerance stack-up.

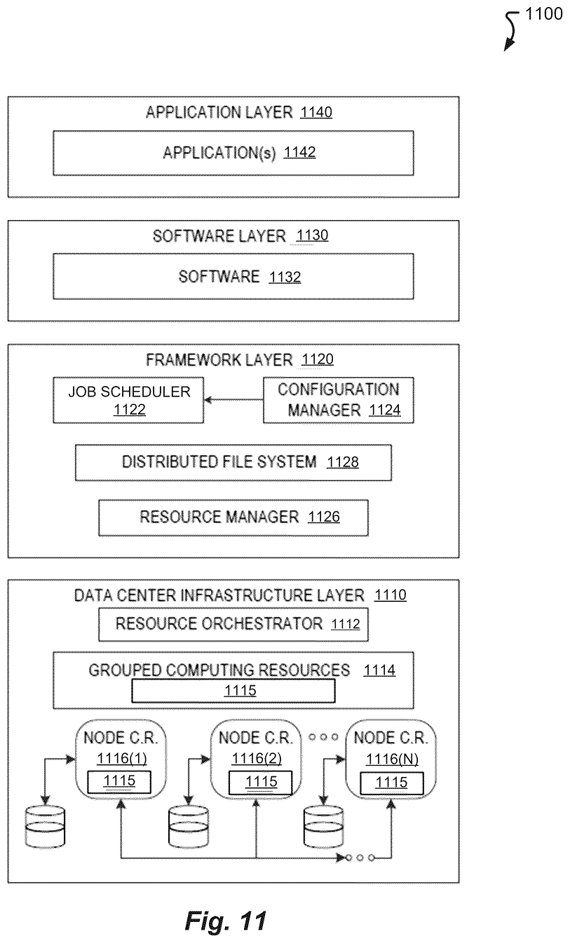

Various aspects and embodiments of a datacenter in which a split heat sink as described above may be used, as well as of components of such a datacenter, will now be described, with reference to FIGS. 10-17. FIG. 10 illustrates a computer system 1000, according to at least one embodiment. In at least one embodiment, the systems and devices described throughout this disclosure may be implemented in connection with a computer system such as the computer system 1000.

In at least one embodiment, computer system 1000 comprises, without limitation, at least one central processing unit (“CPU”) 1002 that is connected to a communication bus 1010 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1000 includes, without limitation, a main memory 1004. Control logic (e.g., implemented as hardware, software, or a combination thereof) and data are stored in main memory 1004 which may take form of random access memory (“RAM”). In at least one embodiment, a network interface subsystem (“network interface”) 1022 provides an interface to other computing devices and networks for receiving data from and transmitting data to other systems from computer system 1000.

In at least one embodiment, computer system 1000, includes, without limitation, input devices 1008, parallel processing system 1012, and display devices 1006 which can be implemented using a conventional cathode ray tube (“CRT”), liquid crystal display (“LCD”), light emitting diode (“LED”), plasma display, or other suitable display technologies. In at least one embodiment, user input is received from input devices 1008 such as keyboard, mouse, touchpad, microphone, and more. In at least one embodiment, each of the foregoing modules can be situated on a single semiconductor platform to form a processing system.

In at least one embodiment, computer programs in the form of machine-readable executable code or computer control logic algorithms are stored in main memory 1004 and/or secondary storage. Computer programs, if executed by one or more processors, enable system 1000 to perform various functions in accordance with at least one embodiment. Memory 1004, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, the architecture and/or functionality of various figures described herein is/are implemented in the context of CPU 1002; parallel processing system 1012; an integrated circuit capable of at least a portion of capabilities of both CPU 1002 and parallel processing system 1012; a chipset (e.g., a group of integrated circuits designed to work and sold as a unit for performing related functions, etc.); and any suitable combination of integrated circuit(s).

In at least one embodiment, the architecture and/or functionality of various figures described herein is/are implemented in the context of a general computer system, a circuit board system, a game console system dedicated for entertainment purposes, an application-specific system, and more. In at least one embodiment, computer system 1000 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1012 includes, without limitation, a plurality of parallel processing units (“PPUs”) 1016 and associated memories 1016. In at least one embodiment, PPUs 1016 are connected to a host processor or other peripheral devices via an interconnect 1018 and a switch 1020 or multiplexer. In at least one embodiment, parallel processing system 1012 distributes computational tasks across PPUs 1016 which can be parallelizable—for example, as part of a distribution of computational tasks across multiple graphics processing unit (“GPU”) thread blocks. In at least one embodiment, memory is shared and accessible (e.g., for read and/or write access) across some or all of PPUs 1016, although such shared memory may incur performance penalties relative to the use of local memory and registers resident to a PPU 1016. In at least one embodiment, operation of PPUs 1016 is synchronized through use of a command such as syncthreads( ), which requires all threads in a block (e.g., executed across multiple PPUs 1016) to reach a certain point of execution of code before proceeding.

Each of the CPU 1002 and the PPUs 1014 illustrated in FIG. 10 may be cooled, for example, using embodiments of the present disclosure.

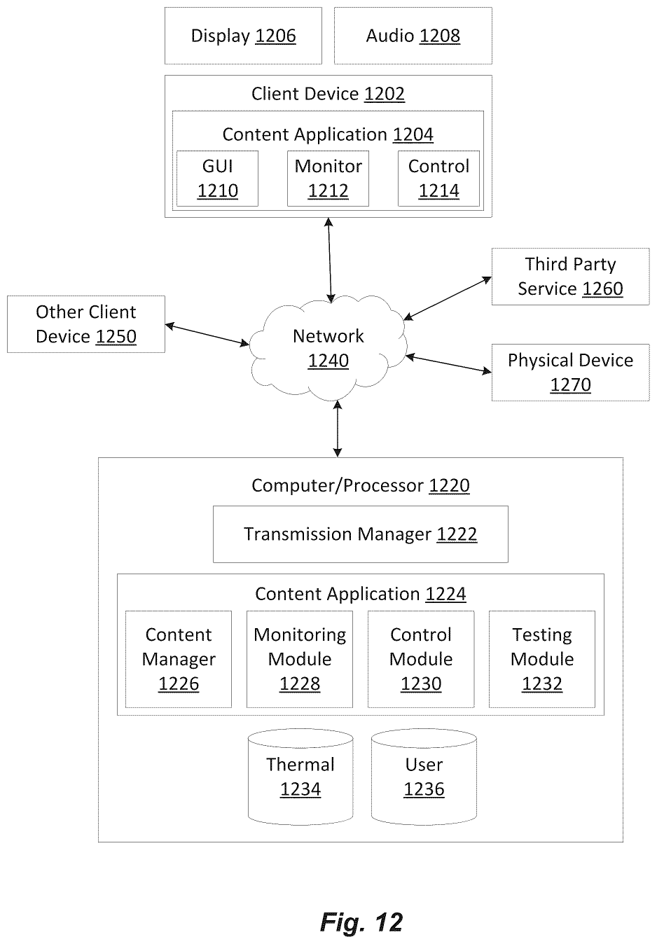

FIG. 11 illustrates additional components of an example datacenter 1100 according to at least some embodiments of the present disclosure. The datacenter 1100 may also include one or more modules subject to one or more cooling/thermal management features as described herein.

In at least one embodiment, datacenter 1100 includes a datacenter infrastructure layer 1110, a framework layer 1120, a software layer 1130, and an application layer 1140. In at least one embodiment, the infrastructure layer 1110, the framework layer 1120, the software layer 1130, and the application layer 1140 may be partly or fully provided via computing components on server trays located in racks of the datacenter 1100 (or of another datacenter). This enables cooling systems of the present disclosure to direct cooling to certain ones of the computing features and the interconnect features, in an efficient and effective manner. Further, aspects of the datacenter 1100, including the datacenter infrastructure layer 1110, the framework layer 1120, the software layer 1130, and the application layer 1140 may be used to support selection or design of the intermediate layers. As such, the discussion in reference to FIG. 11 may be understood to apply to the hardware and software features required to enable or support cooling functionality, for instance.

In at least one embodiment, as in FIG. 11, datacenter infrastructure layer 1110 may include a resource orchestrator 1112, grouped computing resources 1114, and node computing resources (“node C.R.s”) 1116(1)-1116(N), where “N” represents any whole, positive integer. In at least one embodiment, node C.R.s 1116(1)-1116(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 1116(1)-1116(N) may be a server having one or more of above-mentioned computing resources.

In at least one embodiment, grouped computing resources 1114 may include separate groupings of node C.R.s housed within one or more racks (not shown), or many racks housed in datacenters at various geographical locations (also not shown). Separate groupings of node C.R.s within grouped computing resources 1114 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1112 may configure or otherwise control one or more node C.R.s 1116(1)-1116(N) and/or grouped computing resources 1114. In at least one embodiment, resource orchestrator 1112 may include a software design infrastructure (“SDI”) management entity for datacenter 1100. In at least one embodiment, resource orchestrator may include hardware, software or some combination thereof.

In at least one embodiment, as shown in FIG. 11, framework layer 1120 includes a job scheduler 1122, a configuration manager 1124, a resource manager 1126 and a distributed file system 1128. In at least one embodiment, framework layer 1120 may include a framework to support software 1132 of software layer 1130 and/or one or more application(s) 1142 of application layer 1140. In at least one embodiment, software 1132 or application(s) 1142 may respectively include web-based service software or applications, such as those provided by Amazon Web Services, Google Cloud and Microsoft Azure. In at least one embodiment, framework layer 1120 may be, but is not limited to, a type of free and open-source software web application framework such as Apache Spark™ (hereinafter “Spark”) that may utilize distributed file system 1128 for large-scale data processing (such as “big data”). In at least one embodiment, job scheduler 1122 may include a Spark driver to facilitate scheduling of workloads supported by various layers of datacenter 1100. In at least one embodiment, configuration manager 1124 may be capable of configuring different layers such as software layer 1130 and framework layer 1120 including Spark and distributed file system 1128 for supporting large-scale data processing. In at least one embodiment, resource manager 1126 may be capable of managing clustered or grouped computing resources mapped to or allocated for support of distributed file system 1128 and job scheduler 1122. In at least one embodiment, clustered or grouped computing resources may include grouped computing resource 1114 at datacenter infrastructure layer 1110. In at least one embodiment, resource manager 1126 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1128 of framework layer 1120. One or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1128 of framework layer 1120. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 1124, resource manager 1126, and resource orchestrator 1112 may implement any number and type of self-modifying actions based on any amount and type of data acquired in any technically feasible fashion. In at least one embodiment, self-modifying actions may relieve a datacenter operator of datacenter 1100 from making possibly bad configuration decisions and possibly avoiding underutilized and/or poor performing portions of a datacenter.

In at least one embodiment, datacenter 1100 may include tools, services, software or other resources to train one or more machine learning models or predict or infer information using one or more machine learning models according to one or more embodiments described herein. In at least one embodiment, a machine learning model may be trained by calculating weight parameters according to a neural network architecture using software and computing resources described above with respect to datacenter 1100. In at least one embodiment, trained machine learning models corresponding to one or more neural networks may be used to infer or predict information using resources described above with respect to datacenter 1100 by using weight parameters calculated through one or more training techniques. Deep learning may be advanced using any appropriate learning network and the computing capabilities of the datacenter 1100. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 1100 may use CPUs, application-specific integrated circuits (ASICs), GPUs, FPGAs, or other hardware to perform training and/or inferencing using above-described resources. Such hardware may be cooled, for example, using embodiments of the present disclosure. Moreover, one or more software and/or hardware resources described above may be configured as a service to allow users to train or perform inferencing of information, such as pressure, flow rates, temperature, and location information, or as any other artificial intelligence service.

Inference and/or training logic 1115 may be used to perform inferencing and/or training operations associated with one or more embodiments. In at least one embodiment, inference and/or training logic 1115 may be used in a datacenter 1100 (whether in grouped computing resources 1114, in one or more node C.R.s 1116(1)-1116(N), or elsewhere) or in other systems described herein, for inferencing or predicting operations based, at least in part, on weight parameters calculated using neural network training operations, neural network functions and/or architectures, or neural network use cases described herein. In at least one embodiment, inference and/or training logic 1115 may include, without limitation, hardware logic in which computational resources are dedicated or otherwise exclusively used in conjunction with weight values or other information corresponding to one or more layers of neurons within a neural network. In at least one embodiment, inference and/or training logic 1115 may be used in conjunction with an application-specific integrated circuit (ASIC), such as a Tensorflow® Processing Unit from Google, an inference processing unit (IPU) from Graphcore™, or a Nervana® (such as “Lake Crest”) processor from Intel Corp. Such hardware may be cooled, for example, using embodiments of the present disclosure.

In at least one embodiment, inference and/or training logic 1115 may be used in conjunction with central processing unit (CPU) hardware, graphics processing unit (GPU) hardware or other hardware, such as field programmable gate arrays (FPGAs)—each of which may be cooled, for example, using embodiments of the present disclosure. In at least one embodiment, inference and/or training logic 1115 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 1115.

The switches within each layer (e.g., edge layer, aggregation layer, core layer) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

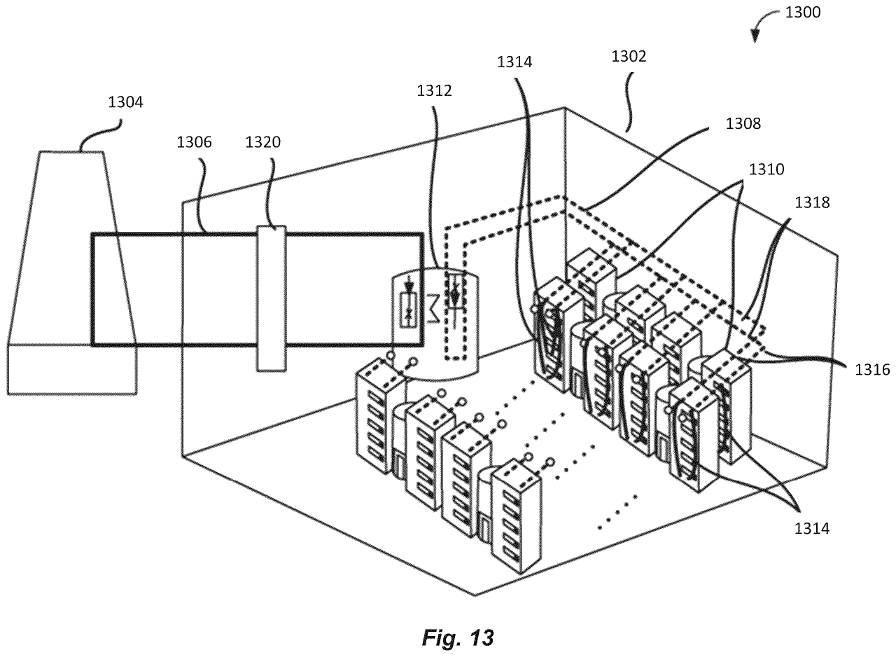

FIG. 12 illustrates an example network configuration 1200 of components that can be used to implement aspects of various embodiments, such as to provide, generate, modify, encode, process, fuse, and/or transmit generated image data, calculated measurements, or other such content. In at least one embodiment, a client device 1202 can generate or receive data for a session using components of a content application 1204 on the client device 1202 and data stored locally on that client device. In at least one embodiment, a content application 1224 executing on a computer or processor 1220 (e.g., a cloud server or control system) may initiate a session associated with at least one client device 1202 (e.g., a vehicle or robot), as may use a session manager and user data stored in a user database 1236, and can cause content such as liquid coolant or server thermal data to be selected and/or retrieved from a repository 1234 to be used by a testing module 1232 to calculate one or more performance metrics for a monitoring module 1228, which can provide flow data or thermal data to a control module 1230 to control a flow or temperature, in an environment where the data is to be used to determine appropriate operation.

A content manager 1226 may work with at least these various modules to perform testing and analysis, and potentially instruct any actions to be taken in response to a performance metric failing to satisfy an operational requirements. At least a portion of this data or instructional content can be transmitted to the client device 1202 and/or a physical device 1270 using an appropriate transmission manager 1222 to send by download, streaming, or another such transmission channel. An encoder may be used to encode and/or compress at least some of this data before transmitting to the client device 1202. In at least one embodiment, the client device 1202 receiving such content can provide this content to a corresponding content application 1204, which may also or alternatively include a graphical user interface 1210, a flow monitor module 1212, and a control module 1214 for use in providing, synthesizing, rendering, compositing, modifying, or using content for presentation, navigation, control, (or other purposes) on or by the client device 1202, such as may be transmitted to the physical device 1270.

In some embodiments, the computer/processor 1220 and client device 1202 may be able to communicate directly without needing to transmit data over a network 1240, in order to avoid issues with latency and availability, etc.. A decoder may also be used to decode data received over the network 1240 for presentation via client device 1202, such as imaging content or performance metrics through a display device 1206 and audio, such as corresponding sounds or synthesized speech, through at least one audio playback device 1208, such as speakers or headphones.

In at least one embodiment, at least some of this content may already be stored on, rendered on, or accessible to client device 1202 such that transmission over a network 1240 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 1220, or user database 1236, to the client device 1202. In at least one embodiment, at least a portion of this content can be obtained, enhanced, and/or streamed from another source, such as a third party service 1260 or other client device 1250, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options.

In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

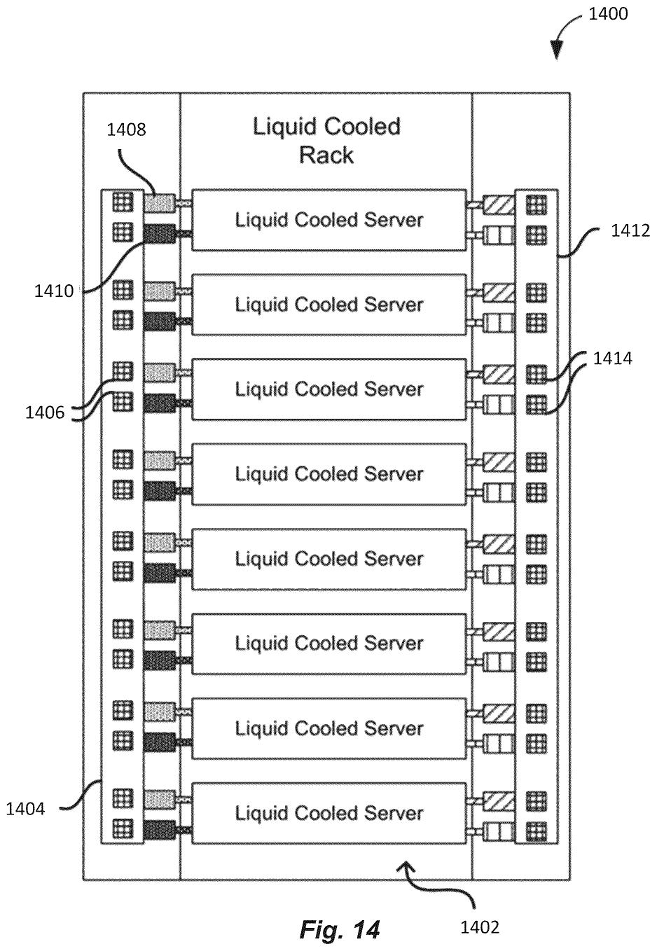

According to at least some embodiments of the present disclosure, an exemplary datacenter 1300 can be utilized as illustrated in FIG. 13, which has a cooling system subject to improvements described herein. Any one or more of the features described above may be utilized in a datacenter such as the datacenter 1300. Numerous specific details are set forth to provide a thorough understanding, but concepts herein may be practiced without one or more of these specific details.

In at least one embodiment, datacenter cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a datacenter. In at least one embodiment, heat generated from these components, servers, and racks are cumulatively referred to as a heat feature or a cooling requirement as cooling requirement must address a heat feature entirely.

In at least one embodiment, a split heat sink system is disclosed. In at least one embodiment, this split heat sink system addresses heat features in associated computing or datacenter devices, including graphics processing units (GPUs), central processing units (CPUs), switches, and dual inline memory modules (DIMMs). In at least one embodiment, these components may be referred to herein as high heat density computing components or simply high-power components. Furthermore, in at least one embodiment, an associated computing or datacenter device may be a processing card having one or more GPUs, switches, or CPUs thereon. In at least one embodiment, each of the GPUs, switches, and CPUs may be a heat generating feature of a computing device. In at least one embodiment, a GPU, a CPU, or a switch may have one or more cores, and each core may be a heat generating feature.

In at least one embodiment, a split heat sink as described above, and more specifically a central heat sink or a first heat sink section as described above, may be thermally coupled to one or more of the high-power components described above. In some embodiments, a liquid cooling system may be used instead of or in addition to (or simply with other datacenter components than) the split heat sink.

In at least one embodiment, an exemplary datacenter 1300 can be utilized as illustrated in FIG. 13, which has a cooling system subject to improvements described herein. In at least one embodiment, a datacenter 1300 may be or comprise one or more rooms 1302 having racks 1310 and auxiliary equipment to house one or more servers on one or more server trays. In at least one embodiment, a datacenter 1300 is supported by a cooling tower 1304 located external to a datacenter 1300. In at least one embodiment, a cooling tower 1304 dissipates heat from within a datacenter 1300 by acting on a primary cooling loop 1306. In at least one embodiment, a cooling distribution unit (CDU) 1312 is used between a primary cooling loop 1306 and a second or secondary cooling loop 1308 to enable absorption of heat from a second or secondary cooling loop 1308 to a primary cooling loop 1306. In at least one embodiment, a secondary cooling loop 1308 can access various plumbing into a server tray as required, in an aspect. In at least one embodiment, loops 1306, 1308 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 1306; 1308. In at least one embodiment, one or more coolant pumps may be used to maintain pressure differences within coolant loops 1306, 1308 to enable movement of coolant according to temperature sensors in various locations, including in a room, in one or more racks 1310, and/or in server boxes or server trays within one or more racks 1310.

In at least one embodiment, coolant in a primary cooling loop 1306 and in a secondary cooling loop 1308 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 1310. In at least one embodiment, a CDU 1312 is capable of sophisticated control of coolants, independently or concurrently, within provided coolant loops 1306, 1308. In at least one embodiment, a CDU may be adapted to control flow rate of coolant so that coolant is appropriately distributed to absorbed heat generated within associated racks 1310. In at least one embodiment, more flexible tubing 1314 is provided from a secondary cooling loop 1308 to enter each server tray to provide coolant to electrical and/or computing components therein.

The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In at least one embodiment, tubing 1318 that forms part of a secondary cooling loop 1308 may be referred to as room manifolds. Separately, in at least one embodiment, further tubing 1316 may extend from row manifold tubing 1318 and may also be part of a secondary cooling loop 1308 but may be referred to as row manifolds. In at least one embodiment, coolant tubing 1314 enters racks as part of a secondary cooling loop 1308 but may be referred to as rack cooling manifold within one or more racks. In at least one embodiment, row manifolds 1316 extend to all racks along a row in a datacenter 1300. In at least one embodiment, plumbing of a secondary cooling loop 1308, including coolant manifolds 1318, 1316, and 1314 may be improved by at least one embodiment herein. In at least one embodiment, a chiller 1320 may be provided in a primary cooling loop within datacenter 1302 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 1310 may be transferred to a coolant exiting one or more racks 1310 via flexible tubing of a row manifold 1314 of a second cooling loop 1308. In at least one embodiment, second coolant (in a secondary cooling loop 1308) from a CDU 1312, for cooling provided racks 1310, moves towards one or more racks 1310 via provided tubing. In at least one embodiment, second coolant from a CDU 1312 passes from one side of a room manifold having tubing 1318, to one side of a rack 1310 via a row manifold 1316, and through one side of a server tray via different tubing 1314. In at least one embodiment, spent or returned second coolant (or exiting second coolant carrying heat from computing components) exits out of another side of a server tray (such as enters left side of a rack and exits right side of a rack for a server tray after looping through a server tray or through components on a server tray). In at least one embodiment, spent second coolant that exits a server tray or a rack 1310 comes out of different side (such as exiting side) of tubing 1314 and moves to a parallel, but also exiting side of a row manifold 1316. In at least one embodiment, from a row manifold 1316, spent second coolant moves in a parallel portion of a room manifold 1318 and is going in an opposite direction than incoming second coolant (which may also be renewed second coolant), and towards a CDU 1312.

In at least one embodiment, spent second coolant exchanges its heat with a primary coolant in a primary cooling loop 1306 via a CDU 1312. In at least one embodiment, spent second coolant may be renewed (such as relatively cooled when compared to a temperature at a spent second coolant stage) and ready to be cycled back to through a second cooling loop 1308 to one or more computing components. In at least one embodiment, various flow and temperature control features in a CDU 1312 enable control of heat exchanged from spent second coolant or flow of second coolant in and out of a CDU 1312. In at least one embodiment, a CDU 1312 may be also able to control a flow of primary coolant in primary cooling loop 1306.

Even in datacenters 1300 that utilize liquid cooling as described above in connection with FIG. 13, split heat sinks such as the split heat sink 100 may be utilized to facilitate the cooling of high-power components and adjacent or neighboring low-power components, which may advantageously improve the serviceability of the adjacent or neighboring low-power components in particular. Removal of a single section of a split heat sink 100 to service an underlying component is substantially easier than removing, for example, an entire liquid-cooled heat sink or cold plate such as those described in connection with FIG. 13.

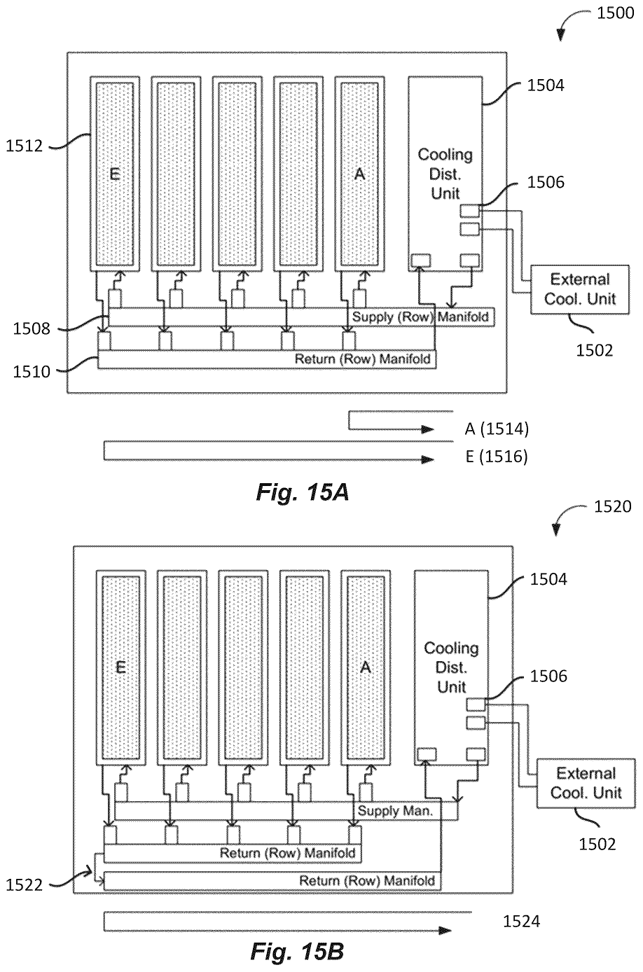

Turning now to FIG. 14, in at least one embodiment, neural networks can be embedded in various devices to enable those devices to predict future state, and make proactive adjustments based at least in part upon those predictions. In at least one embodiment, this can include neural network enabled devices to be installed directly in a liquid cooled server rack 1400. In at least one embodiment, rack 1400 can include a number of liquid cooled servers 1402 or other such devices. In at least one embodiment, a neural network enabled rack manifold 1404 can be included in rack 1400 to provide a flow of liquid into each liquid cooled server 1402 through an inlet valve 1408, and return liquid with heat removed from that server 1402 through an outlet valve 1410. In at least one embodiment, rack manifold 1404 can include a number of neural network-enabled secondary liquid distribution control boards 1406. In at least one embodiment, there can be one such control board 1406 for each inlet valve 1408 and outlet valve 1410 for each server. In at least one embodiment, rack 1400 can also include a neural network-enabled rack power distribution unit (PDU) 1412, which can include multiple outlets designed to distribute electric power to computers or networking equipment within rack 1400. In at least one embodiment, there can be a neural network-enabled power distribution control board 1414 associated with each outlet of PDU 1412. In at least one embodiment, sensors can capture information about temperature, air flow, or other such aspects of a computing environment internal and/or external to rack 1400, including internal and/or external to any individual servers 1402 located therein. In at least one embodiment, fluid cooling can remove an amount of heat from servers 1402, but due to factors such as varying load and external temperature fluctuations, temperatures at various locations may change, and may reach or exceed temperature limits at which these devices can continue to operate correctly. In at least one embodiment, an attempt can be made to ensure that temperatures at specific locations remain below an acceptable limit, where those locations may relate to junction temperatures or core temperatures for a processor (e.g., a CPU or GPU), memory module, or power supply.

In at least one embodiment, neural networks in these control boards 1406, 1414 can be tasked to predict values such as coolant flow or air flow, as well as temperatures at these various locations at one or more future points in time. In at least one embodiment, predictions from these networks can be used by a respective board, manifold, PDU, or other such device to make adjustments to ensure appropriate temperature and flow and keep this equipment functioning properly. In at least one embodiment, these adjustments can include adjusting an amount of fluid or air flowing into, or out of, a server, a split heat sink, or another device, as well as a temperature of that fluid or air. In at least one embodiment, this may also include adjusting an amount of power supplied to one or more of these devices and/or to a fan that controls air flow around these devices. In at least one embodiment, these can include similar adjustments as would be made in other data centers, but can be made based on future predictions instead of observed states, enabling such a system to be proactive instead of reactive. In at least one embodiment, this monitoring can occur continually or at least at regular intervals, in order to ensure proper continued operation.

In at least one embodiment, each neural network in each type of component can be trained specifically for that type of component, and can receive updated network parameters that may be generated as a result of further training or continued learning. In at least one embodiment, inferences generated by individual devices can be shared with other devices in a data center as well, which can help to make more accurate predictions. In at least one embodiment, each control board 1406, 1414 can be a neural network enabled board, ASIC, or other such component. In at least one embodiment, a control board can have components of a general-purpose computer, including at least one processor (such as the CPU 1002 of FIG. 10) and memory (such as the main memory 1004 of FIG. 10 or the memory modules 808A, 808B of FIG. 8) with associated circuitry. In at least one embodiment, a Jetson board from NVIDIA Corporation can be used that is a complete system-on-module (SPM), with CPU, GPU, PMIC, DRAM, and flash storage included therein. In at least one embodiment, such a module is also extensible to provide additional functionality or capabilities. In at least one embodiment, each such board can function as a small artificial intelligence (AI) or machine learning enabled computer. In at least one embodiment, multiple such boards can be used in parallel, such as on rack manifold 1404, in order to concurrently process data from multiple high-resolution sensors. In at least one embodiment, these various neural networks can make predictions that can be shared across servers, a rack, or a data center, for example, in order to provide accurate predictions for various locations at one or more future points in time. In at least one embodiment, appropriate adjustments can then be made as appropriate in order to maintain temperatures and other parameters at appropriate levels or values. In at least one embodiment, a liquid distribution control board 1406 may make predictions that can be used to adjust only controls for a relevant flow value, or may share these predictions so that other adjustments can be made as well based at least in part upon these predictions. In at least one embodiment, a control system for a data center may collect predictions from these various boards or networks in order to make adjustments that are more appropriate for an overall data center. In at least one embodiment, adjustments can then be made at a server, rack, pod, data center, or other such level.

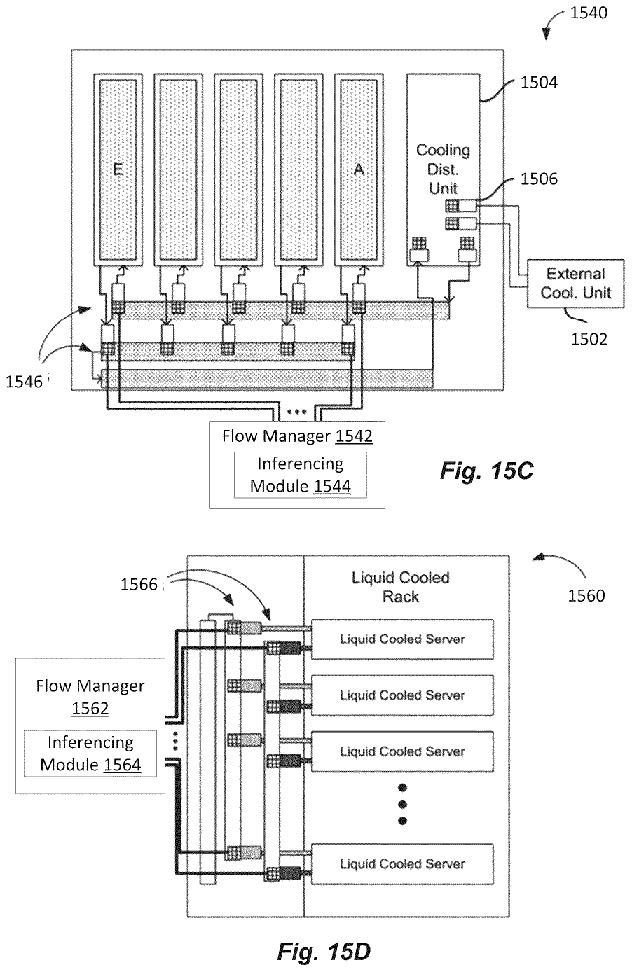

In at least one embodiment, a neural network-enabled approach to liquid cooling of racks at a data center level can utilize components of a system 1500 illustrated in FIG. 15A. In at least one embodiment, an external cooling unit 1502 can provide liquid at a determined temperature to a data center cooling distribution unit 1504. In at least one embodiment, this unit 1504 can include a set of neural network-enabled distribution unit control boards 1506, which can perform inferencing and make adjustments based upon inferred future values. In at least one embodiment, this can include adjusting a temperature of liquid to be received from external cooling unit 1502, or adjusting a flow of that liquid to and/or from that external unit 1502. In at least one embodiment, this can also include adjusting flow into a manifold 1508 for a row of liquid cooled racks 1512, as well as flow into and out of those racks, as may be determined based at least in part upon inferences from neural network-enabled control boards 1510 built into row manifold 1510. In at least one embodiment, there can be different levels of flow into, and out of, different liquid cooled racks. In at least one embodiment, there may also be different flows into individual servers in a rack, such as is described with respect to FIG. 14. In at least one embodiment, a similar approach can be used for an air-cooled data center. In at least one embodiment, temperature and air flow can be measured and predictions made for future values, at times such as 30 seconds, one minute, five minutes, or an hour into our future, which can then enable adjustments to be made to air temperature, air flow, power distribution, and other such aspects. In at least one embodiment, these predictions can be made using various types of input data, such as server load, current temperature, current pressure, flow rate, power consumption, and other pertinent data for various locations within that data center.

In at least one embodiment, these neural network-enabled boards can control an amount of air or liquid flow, supply, and return at various locations, such as at a rack, server, or GPU-level. In at least one embodiment, these boards can be used to predict, control, and create an optimal solution for such a data center to maintain desired operating conditions, with no loss of equipment or downtime due to temperature issues or thermal events. In at least one embodiment, this can be based on current and anticipated load, as well as measured or detected network conditions. In at least one embodiment, this approach can be applied to other types of devices as well, as may include UPS power supplies. In at least one embodiment, any device with a logic board or component can have this small neural network code injected for these and other such purposes. In at least one embodiment, such a network can tap into all equipment available in a unit or device, such that in a device such as a PDU a board can adjust or cut power completely to a server node, such as where a leak is detected or predicted and relevant equipment may be subject to damage if operation continues. In at least one embodiment, operation can be terminated, or power shut down, gracefully in order to avoid damage. In at least one embodiment, executing programs may instead be terminated in order to at least avoid a loss of data.

In at least one embodiment, a cooling system can utilize a direct return design, as illustrated in FIG. 15A. In at least one embodiment, coolant from a CDU 1504 is directed along a supply manifold 1508 into individual server racks. In at least one embodiment, a first server rack (A) will receive liquid first along this flow, and a last server rack (E) will receive liquid last along this flow. In at least one embodiment, a return manifold 1510 will be used to receive heated liquid passing from these racks and return that heated liquid to CDU 1504. In at least one embodiment, heated liquid returned from first server rack (A) will have a shortest return path, with last server rack (E) having a longest return path. In at least one embodiment, this results in an overall liquid path 1514 for first server rack (A) that is much shorter than an overall liquid path 1516 for last server rack (E) 1516. In at least one embodiment, there can be significant variation is aspects such as pressure and flow throughout a loop of a cooling system. In at least one embodiment, this may include lower pressure near ends of a cooling loop and higher pressure in a middle portion of that loop. In at least one embodiment, such an imbalanced design can result in unacceptable variation in flow rate across a data center or other environment as different path lengths will result in different pressures, temperatures, and other environmental aspects impacting those flows. In at least one embodiment, different amounts of time needed for this liquid to travel along these different paths can also lead to flow variation.

In at least one embodiment, a reverse return-based design can be utilized as illustrated for system 1520 of FIG. 15B. In at least one embodiment, this system includes a reverse return manifold 1522 that receives heated liquid from first server rack (A) first and last server rack (E) last, but instead of directing that flow back directly to CDU 1506 causes liquid to pass from first to last server, or right to left in FIG. 15B, then back through a second portion to CDU 1504. As illustrated, liquid for each server rack will follow a path of similar length 1524, at least through respective manifolds. In at least one embodiment these path lengths may effectively be equal, allowing for slight variations based upon factors such as placement and component type. In at least one embodiment, liquid for each server rack will flow through essentially an entire length of this supply manifold and this return manifold, instead of different portions as in a direct return design of FIG. 15A. In at least one embodiment, this can cause liquid for all server racks to go through these same variations in temperature, pressure, and other environmental parameters encountered throughout a full run of this manifold. In at least one embodiment, such a balanced design can help to reduce variation in flow rate for liquid delivered to different locations throughout this cooling system. In at least one embodiment, this can help to ensure that flow variation is maintained within a desired range, or less than a maximum variation threshold. In at least one embodiment, such a balanced design can help to ensure equal and sufficient liquid is delivered to all servers and racks in a data center by respective cooling components of a liquid cooling system.

In at least one embodiment, all supply and return fluid lines between one or more CDUs and one or more direct-to-chip (D2C) cold plates cooling loops or heat exchangers in an immersive liquid cooled blade can utilize a reverse return, as opposed to a direct return, in various data center collectors, row manifolds, and rack manifolds. In at least one embodiment, electronic valve controls at each of outlets from these collectors, row manifolds, and rack manifolds can have an ability to both monitor and control a flow of primary and/or secondary fluids to, and from, these CDUs leading to cold plates attached to components, such as CPUs, GPUs, and switches, as well as other D2C liquid cooled components and blade immersion servers. In at least one embodiment, a liquid cooling system can utilize a combination of a self-balancing flow design in all primary and secondary loops, along with electronic monitoring and control utilizing AI or machine learning, based at least in part upon data received from various flow rate, pressure, temperature, power, and other environmental or operational sensors. In at least one embodiment, such an approach can provide for improved or optimized liquid distribution liquid cooled components, such as servers and processors, in environments such as data centers

In at least one embodiment, neural network-based flow control can be used with such a design to provide for further variation minimization or flow consistency. In at least one embodiment, a combination of self balancing along with electronics monitoring and control can provide for very balanced and optimized flow of coolant to each of server, rack, processor, or other such component without these components fighting each other and without requiring extensive control schemes. In at least one embodiment, flow controllers can be located at various locations throughout a cooling system, such as may be used to direct coolant into, and out of, components such as racks, servers, and electronic components, where that liquid can be provided using pathways such as row and rack manifolds. In at least one embodiment, these flow controllers can allow for incremental control (e.g., partial opening and closing) to provide for an accurate, self-balancing approach. In at least one embodiment, a self-balancing design with fine adjustable control can provide for accurate balancing of liquid flow across various, if not all, outlets of a liquid cooling system. In at least one embodiment, such an approach can be used to provide a flow of, for example, 50 liters per minute (lpm) with a tolerance, threshold, or variation range of +/−5 lpm, whereas a design without such an approach might have a flow of around 60 lpm at one location and around 40 lpm at another due to differences such as pressure gradients and gravitational effects, which can be an unacceptable flow imbalance across a system.

In at least one embodiment, a control system 1540 can be implemented as illustrated in FIG. 15C. In at least one embodiment, a reverse return row manifold design can be utilized to provide for a balance of pressure and flow across this system. In at least one embodiment, controllable flow valves 1546 can be used at various inlet and/or outlet locations, such a inlets and outlets to individual racks from a row manifold. In at least one embodiment, a flow manager 1542 can receive data from various sensors, devices, or data sources across a relevant environment. In at least one embodiment, this flow manager 1542 can provide at least some of this data as input to one or more neural networks (e.g., deep neural networks (DNNs)) of an inferencing module 1544. In at least one embodiment, sensors and valves can be calibrated for a type of fluid utilized. In at least one embodiment, there may be one flow manager 1542 for an entire data center or environment, or there can be flow managers for individual rows, racks, or servers. In at least one embodiment, neural networks can be utilized at each individual flow control valve as well, as may communicate with one or more separate flow controllers. In at least one embodiment, flow manager 1542 can receive one or more inferences from inferencing module 1544, where those inferences may include adjustments or settings for individual flow control valves. In at least one embodiment, flow manager 152 can then send this or related data or instructions to these individual flow control valves 1546, or other such components, to make small adjustments to help balance flow across this system.

In at least one embodiment, such an approach can be used at a rack level or server level as well as illustrated in system 1560 of FIG. 15D. In at least one embodiment, a liquid cooled rack can have a rack manifold that utilizes a reverse return design, so that liquid path lengths for individual servers of a rack are equivalent as well. In at least one embodiment, a size of this manifold can be much smaller than a size of a corresponding rack, as FIG. 15D illustrates an exploded view for clarity of explanation. In at least one embodiment, a flow manager 1562 can utilize an inferencing module 1564 to determine adjustments to be made to individual flow control valves 1566 within a rack, to balance flow across individual servers in a rack. In at least one embodiment, a flow manager can provide such instructions to flow control valves or components within a server as well, such as may be used to direct coolant for specific cold plates, processors, or other internal server components. In at least one embodiment, use of these intelligent control valves can provide for well-balanced plumbing distribution and controllability. In at least one embodiment, each of these smart control valves 1566 can marginally adjust itself as appropriate, as may be under direction of a flow manager. In at least one embodiment, these flow valves may utilize PID or PIV servo control, where PIV allows for control based on both position and velocity errors.

In at least one embodiment, one or more neural networks can be trained to infer an amount of liquid cooling needed for various components under various circumstances. In at least one embodiment, this may include determining how much additional cooling may be needed for a GPU that goes to 500 Watts of operational power from a more normal 300 Watts, which may require 1.7 lpm instead of 1.0 lpm. In at least one embodiment, this neural network can infer an adjustment to be made to liquid flow for that component, and can enable an accurate adjustment to be made proactively in order to avoid a significant temperature fluctuation from resulting. In at least one embodiment, there may be one or more tables of operations that may correlate factors such as proportional flow rate with power dissipation, which can be used to train these models or used to determine adjustments based on inferred state data. In at least one embodiment, these tables can also be used for different types of components, or different models of a same type of component, in order to account for differences inherent to these components themselves. In at least one embodiment, inferences can be made at different levels of granularity, from an overall data center level to a level of an internal server component such as a GPU. In at least one embodiment, data can be gathered by a component such as a board management controller (BMC) or a server and provided through a networking port to a flow manager, which can send instructions to one or more flow controllers to make one or more appropriate adjustments.

In at least one embodiment, a neural network can predict fluid state at various locations at one or more future times based at least in part upon available information. In at least one embodiment, this can include a snapshot of current information, or may include at least some data over a recent past. In at least one embodiment, these predictions can then be used to adjust aspects such as flow rate. In at least one embodiment, a cooling distribution unit may adjust a flow of liquid or coolant temperature. In at least one embodiment, such equipment can take these predictions and be proactive in order to prevent any undesirable events before they occur. In at least one embodiment, a variety of sensors may provide information about a current state of a computing environment. In at least one embodiment, this may include use of sensors such as temperature sensors, load sensors, flow sensors, or pressure sensors, which can be instantaneously or historically gathered. In at least one embodiment, predictions made based on data from these sensors may be compared to one or more thresholds, ranges, or other operational criteria to determine whether any changes should be made. In at least one embodiment, this can include making an adjustment to prevent an unacceptable temperature rise at a specific location within a data center or other such environment. In at least one embodiment, this may include closing a valve or increasing an amount of coolant flow, adjusting a coolant temperature, or sounding an alarm, among other such remedial actions.

In the packaging of integrated circuit (IC) chips, various packaging schemes are employed, including traditional two-dimensional (2D) integrated circuit (IC) packages as well as the more recently introduced 2.5D IC and 3D IC packages. In 2D IC packages, multiple chips are mounted on a printed circuit board, where high-performance logic, lower-performance logic, memory, and analog/RF functions, and other functional elements are presented as discrete devices in separate chip packages. By contrast, in 2.5D ICs and 3D IC packages, multiple IC chips are mounted on a silicon interposer instead of a conventional package substrate. The silicon interposer, which is typically a silicon wafer, allows very small and high-density conductive traces to be formed between the multiple IC chips because the fabrication processes used to form the conductive traces are the same processes used to form the metal interconnects in the metalization layers of a silicon chip.

Compared to 2.5D IC packages and 3D IC packages, a circuit board with individually packaged chips, such as a 2D IC package, has numerous disadvantages. For example, a 2D IC package is generally larger, heavier, consumes more power, and, because the signals propagate relatively slowly across the circuit board from one chip to another, is slower than an equivalent 2.5D or 3D IC package. Furthermore, a 2D IC package has more possible points of failure, given that the soldered joints on the circuit board are more likely to fail than the electrical connections formed within an interposer. That said, troubleshooting a 2D IC package after the different chips have been mounted on the circuit board is relatively straightforward. In particular, the conductive traces carrying I/O signals between the various chips on the circuit board are easily accessible and therefore can be employed to measure specific I/O signals during troubleshooting.

By contrast, troubleshooting a 2.5D or 3D IC package is far more problematic because the I/O signals transmitted between the different chips typically are embedded in the silicon interposer and are not physically accessible. Furthermore, because 2.5D and 3D IC packages are high-bandwidth and are quite dense, typically implementations can include thousands of conductive traces routed between the different chips. One example of such an implementation is a memory bus residing in between a processor and a high-bandwidth memory chip. In such implementations, even if the traces could be physically accessed through the silicon interposer with a probe, the accurate and reliable selection of a specific conductive trace or combination of conductive traces for the purpose of troubleshooting the IC package would be very difficult, if not impossible.

In at least one embodiment, one or more parallel processor(s) (such as the parallel processing units 1014 of the parallel processing system 1012) incorporate circuitry optimized for graphics and video processing, including, for example, video output circuitry, and constitutes a graphics processing unit (“GPU”). In at least one embodiment, one or more parallel processor(s) incorporate circuitry optimized for general purpose processing. In at least embodiment, components of computing system (such as the computer system 1000) may be integrated with one or more other system elements on a single integrated circuit. For example, in at least one embodiment, one or more parallel processor(s), a memory hub (such as the main memory 1004 of the computer system 1000), one or more processor(s) (such as the CPU 1002 of the computer system 1000), and an I/O hub (which may facilitate communication with, for example, one or more display devices 1006, one or more input devices 1008, and/or a network interface 1022 of a system such as the computer system 1000) can be integrated into a system on chip (SoC) integrated circuit. In at least one embodiment, components of such a computing system can be integrated into a single package to form a system in package (“SIP”) configuration. In at least one embodiment, at least a portion of components of such a computing system can be integrated into a multi-chip module (“MCM”), which can be interconnected with other multi-chip modules into a modular computing system. In at least one embodiment, an I/O subsystem and any display devices are omitted from such a computing system.

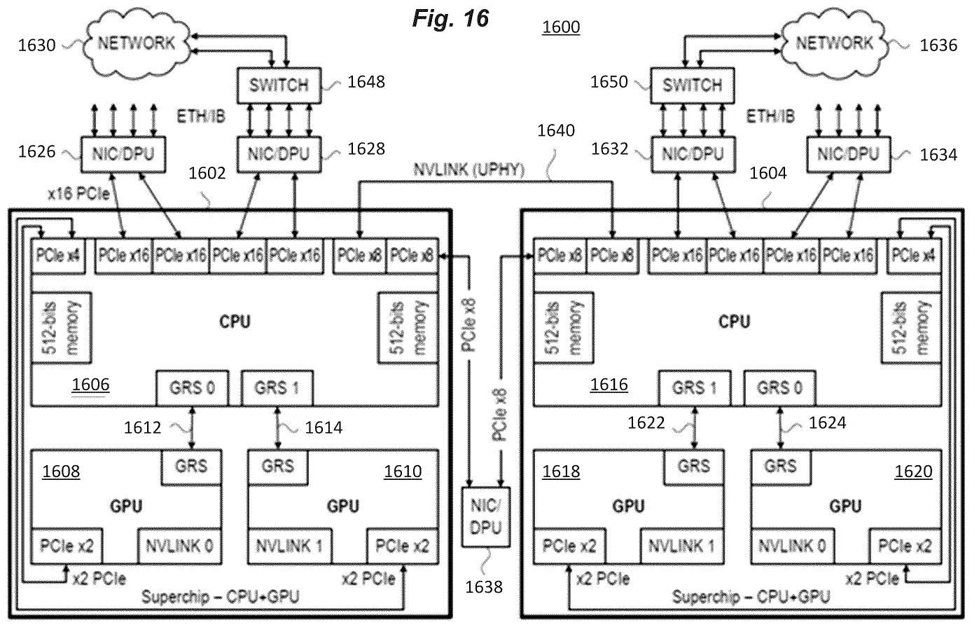

FIG. 16 is a block diagram that schematically illustrates a computing system 1600, e.g., a data center or a High-Performance Computing (HPC) cluster, in accordance with an embodiment that is described herein. System 1600 comprises a plurality of subsystems, e.g. multiple processing devices coupled to each other, multiple network devices, and multiple networks, according to at least one embodiment. Computing system 1600 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1600 and to one or more external networks 1630, 1636. In the present example, system 1600 comprises a packet switch 1648 that connects NIC/DPU 1628 to network 1630, and a packet switch 1650 that connects NIC/DPU 1632 to network 1636.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs.

FIG. 16 also demonstrates an example architecture of a multi-GPU architecture. As illustrated in the figure, computing system 1600 includes a processing device 1602 with a multi-GPU architecture. In particular, processing device 1602 may be a system-on-chip and includes multiple subsystems such as a CPU 1606, a GPU 1608, and a GPU 1610. CPU 1606 can be coupled to GPU 1608 via a die-to-die (D2D) or chip-to-chip (C2C) interconnect 1612, such as a Ground-Referenced Signaling interconnect (GRS interconnect). CPU 1606 can be coupled to GPU 1610 via a D2D or C2C interconnect 1614. CPU 1606 can also couple to GPU 1608 and GPU 1610 via PCIe interconnects.

CPU 1606 can be coupled to one or more NICs or DPUs, which are coupled to one or more networks. For example, as illustrated in FIG. 16, CPU 1606 is coupled to a first NIC/DPU 1626, which is coupled to a network 1630. CPU 1606 is also coupled to a second NIC/DPU 1628, which is coupled to network 1630 via switch 1648. NIC/DPU 1626 and NIC/DPU 1628 can be coupled to network 1630 over Ethernet (ETH), NVLINK or InfiniBand (IB) connections, for example.

Computing system 1600 also includes a processing device 1604 with a multi-GPU architecture. In particular, processing device 1604 includes multiple subsystems including a CPU 1616, a GPU 1618, and a GPU 1620. CPU 1616 can be coupled to GPU 1618 via an D2D or C2C interconnect 1622. CPU 1616 can be coupled to GPU 1620 via a D2D or C2C interconnect 1624. CPU 1616 can also couple to GPU 1618 and GPU 1620 via PCIe interconnects. CPU 1616 can be coupled to one or more NICs or DPUs, which are coupled to one or more networks. For example, as illustrated in FIG. 16, CPU 1616 is coupled to a first NIC/DPU 1632, which is coupled to a network 1636. CPU 1616 is also coupled to a second NIC/DPU 1634, which is coupled to network 1636 via switch 1650. NIC/DPU 1632 and NIC/DPU 1634 can be coupled to network 1636 over Ethernet (ETH), NVLINK or InfiniBand (IB) connections.

In at least one embodiment, processing device 1602 and processing device 1604 can communicate with each other via a NIC/DPU 1638, such as over PCIe interconnects. Processing device 1602 and processing device 1604 can also communicate with each other over high-bandwidth communication interconnects 1640, such as an NVLink interconnect or other high-speed interconnects. The packet switches in FIG. 16 may comprise, for example, Nvidia Quantum-2 switches. The NICs/DPUs in the figure may comprise, for example, Nvidia Bluefield DPUs.

Cooling systems such as the system 100 described above in connection with FIG. 1—including cooling systems having a pedestal such as the pedestal 128A, 128B with a contact surface such as the contact surface 116 and at least one pressure surface such as the pressure surface 120 —may be utilized to cool one or more of the components of the system 1600. For example, such a cooling system may be used to cool one or more of the CPUs 1606 and 1616, one or more of the GPUs 1608, 1610, 1618, and 1620, the entire superchip comprising the CPU 1606 and the GPUs 1608 and 1610, and/or comprising the CPU 1616 and the GPUs 1618 and 1620, and or any other physical, heat-producing component of the system 1600.

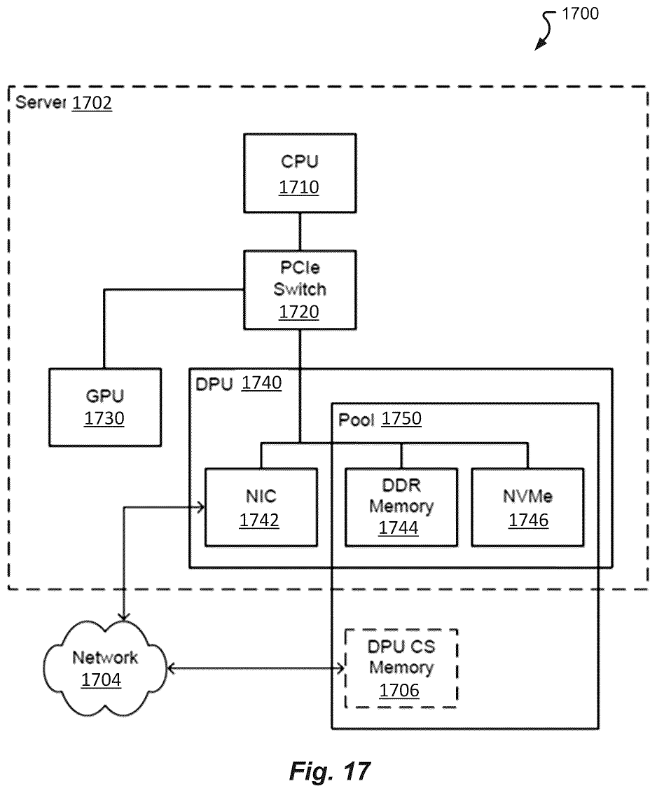

FIG. 17 illustrates an example computing environment 1700 according to at least one embodiment of the present disclosure in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1700 may include a server 1702 which may be used to perform HPC workloads, such as AI training or machine learning model training. In an embodiment, the server 1702 may be an application instance or a compute node. The server 1702 may include a CPU 1710 associated with a switch 1720, such as a peripheral component interconnect express (PCIe) switch, which may control at least some data transmission over communication paths interconnecting various components. In an embodiment, the CPU 1710 may include a root complex processor.

The PCIe switch 1720 may also be associated with a GPU 1730 and a DPU 1740, and may transmit data between at least some of the CPU 1710, the G7PU 130, the DPU 1740, and other components. In an embodiment, the PCIe switch 1720 may be associated with more than one GPU or more than one DPU. In another embodiment, the PCIe switch 1720 may be located within the DPU 1740. The PCIe switch 1720 may manage the transfer of at least some data between the CPU 1710, the GPU 1730, and the DPU 1740. In another embodiment, the number of GPUs associated with the PCIe switch 1720 may be equal to the number of DPUs associated with the PCIe switch 1720. In at least one embodiment, the server 1702 may include, without limitation, any number of the CPUs 1710, the PCIe switches 1720, the GPUs 1730, and/or the DPUs 1740, in any combination. For example, in at least one embodiment, server 1702 could include eight, sixteen, thirty-two, and/or more GPUs 1730. In at least one embodiment, communication paths interconnecting various components, including but not limited to the CPU 1710, the PCIe switch 1720, the GPU 1730, and the DPU 1740, in FIG. 17 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1740 may include a network interface controller (NIC) 1742, a DDR memory 1744, and a non-volatile memory express (NVMe) device 1746. The NIC 1742 may be able to interface with a network 1704, which may also interface with additional NVMe devices available to the DPU 1740, such as over fabric. In an embodiment, the DPU 1740 may not include the NVMe device 1746. In another embodiment, the NVMe device 1746 may be located on the server 1702 and not on the DPU 1740. In yet another embodiment, the computing environment 1700 may include more than one of the NVMe device 1746, such as a first NVMe device in the DPU 1740 and a second first NVMe device on the server 1702 an associated directly with the PCIe switch 1720. In an embodiment, the DPU 1740 may not include the DDR memory 1744 and may include a computational storage services (CSS) in place of, or in addition to, the DDR memory 1744. For example, the computing environment 1700 may include DPU computational storage (CS) memory 1706 available to the DPU 1740 as part of the CSS. The network 1704 may be able to interface with the DPU CS memory 1706 through the NIC 1742, according to any suitable interface protocol, such as remote direct memory access (RDMA) over Ethernet, InfiniBand, Fiber Channel, etc..

The total memory of the computing environment 1700 available for data storage may be expanded through the use of the DPU 1740 on nodes of the system. The DPU 1740 may have access to a pool 1750 of memory already available to the server 1702, such as double data rate (DDR) memory, on-board NVMe devices, NVMe devices over fabric, and CS. The pool 1750 of memory may include at least one of the DDR memory 1744, NVMe 1746, and the DPU CS memory 1706. The DPU 1740 may also be able to access the available memory of other DPUs as part of the pool 1750, and other DPUs may be able to access the available memory of DPU 1740, such as the pool 1750. This available memory can be accessed and utilized for data storage, without the addition of compute resources, such as compute nodes, which would be required using other solutions. The available pool 1750 accessible to the DPU 1740 may be provisioned for the server 1702 to expand the total memory available for data storage, such as to reduce the data storage load on the CPU 1710 or the GPU 1730, which can instead increase the utilization of their memory for processing. For example, during training of an AI, the model states, residual states, activation functions, and checkpoints can be stored, or offloaded, on the pool 1750 accessible to the DPU 1740.

Embodiments of the present disclosure may comprise any suitable material known in the art (e.g., carbon steel, aluminum, polymers, ceramics, and the like), particularly materials possessing high thermal conductivity. By way of example, components as described herein may be created by an extrusion and/or machine process. In such an example, a single body of fixed cross-sectional area may be produced by an extrusion process.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with components described herein. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A heat sink, comprising:
a first section to extract heat generated by a high-power component; and
at least a second section, attachable to and detachable from the first section, to extract heat generated by a low-power component, wherein the at least a second section, when attached to the first section, is thermally coupled to the first section such that the heat generated by the high-power component is further dissipated by the at least a second section.

2. The heat sink of claim 1, wherein the high-power component comprises at least one of a Graphics Processing Unit (GPU) and Central Processing Unit (CPU).

3. The heat sink of claim 1, wherein the low-power component comprises a pluggable module.

4. The heat sink of claim 3, wherein the memory module comprises at least one of a Small Outline Compression Attached Memory Module (SOCAMM), a Dual In-Line Memory Module (DIMM), a network module, an optical module, a re-timer, and an Mid-Board Optical Module (MBOM).

5. The heat sink of claim 1, wherein the low-power component is serviceable without detaching the high-power component from the first section.

6. The heat sink of claim 1, wherein the first section is attached to the at least a second section with one or more screws.

7. The heat sink of claim 1, wherein the at least a second section accommodates one or more heat pipes.

8. The heat sink of claim 7, wherein the one or more heat pipes are thermally coupled with the first section and conduct heat from the first section into the at least a second section.

9. The heat sink of claim 1, wherein the first section and the at least a second section both comprise one or more finned structures.

10. The heat sink of claim 1, wherein the at least a second section comprises a second section thermally coupled with a first low-power component and a third section thermally coupled with a second low-power component.

11. The heat sink of claim 10, wherein the first section is positioned between the second section and the third section.

12. A system, comprising:
a processing unit;
a first memory module;
a first heat sink section to extract heat generated by the processing unit; and
a second heat sink section to extract heat generated by the first memory module, wherein the second heat sink section is attachable to and detachable from the first heat sink section, and wherein the first and second heat sink sections, when attached, collectively transfer heat from the processing unit.

13. The system of claim 12, further comprising:
a Printed Circuit Board (PCB) that is attached to both the processing unit and the first memory module.

14. The system of claim 13, wherein the PCB carries electrical signals between the processing unit and the first memory module.

15. The system of claim 12, further comprising:
a second memory module; and
a third heat sink section to extract heat generated by the second memory module, wherein the third heat sink section is attachable to and detachable from the first heat sink section, and wherein the first and third heat sink sections, when attached, collectively transfer heat from the processing unit.

16. The system of claim 12, wherein the first memory module is serviceable by detaching the first heat sink section from the second heat sink section.

17. The system of claim 12, further comprising:
a stiffener base that provides structural support for the first heat sink section and that provides a connection interface between the first heat sink section and the second heat sink section.

18. The system of claim 17, further comprising:
a Thermal Interface Material (TIM).

19. The system of claim 18, wherein the TIM is provided between the stiffener base and the second heat sink section or between the second heat sink section and the first memory module, wherein the TIM comprises at least one of a grease, a gap pad, a phase change material, and a putty, wherein the TIM provides a substantially uniform cooling between the stiffener base, the first heat sink, and/or the second heat sink, and wherein the TIM accommodates a tolerance difference between the stiffener base, the first heat sink section, the second heat sink section, the processing unit, and/or the memory module.

20. A split heat sink comprising:
a central heat sink configured to extract heat generated by a processing unit; and
a first side wing heat sink configured to extract heat generated by a memory module, the first side wing heat sink comprising at least one heat pipe and at least one fin;
wherein the first side wing heat sink is removably attachable to the central heat sink and configured to also extract a portion of the heat generated by the processing unit when attached to the central heat sink.
